(19) United States
(12) Patent Application Publication
(10) Pub. No.: US 2015/0270123 A1
(43) Pub. Date: Sep. 24, 2015

(54) Liquid Chemical for Forming Protective Film

(71) Applicant: CENTRAL GLASS COMPANY LIMITED, Yamaguchi (JP)

(72) Inventors: Shinobu Arata, Matsusaka-shi (JP); Soichi Kumon, Matsusaka-shi (JP); Masanori Saito, Matsusaka-shi (JP); Takashi Saio, Nabari-shi (JP)

(73) Assignee: CENTRAL GLASS COMPANY, LIMITED, Yamaguchi (JP)

(21) Appl. No.: 14/430,783

(22) PCT Filed: Sep. 12, 2013
(86) PCT No.: PCT/JP2013/074652

§ 371 Date: Mar. 24, 2015

(30) Foreign Application Priority Data
Sep. 25, 2012 (JP) 2012-210883

(51) Int. Cl. H01L 21/02; C09D 7/12; B08B 3/04

(52) U.S. Cl. CPC H01L 21/02068; B08B 3/04; C09D 7/1233

(57) ABSTRACT

A liquid chemical for forming a water-repellent protective film, containing: a water-repellent protective film forming agent for forming a water-repellent protective film on a wafer having at its surface an uneven pattern and containing at least one kind of element selected from titanium, tungsten, aluminum, copper, tin, tantalum and ruthenium at surfaces of recessed portions of the uneven pattern, the protective film being formed at least on the surfaces of the recessed portions by retaining the liquid chemical at least on the recessed portions of the wafer before a rinsing treatment step of rinsing the wafer surface with a rinsing liquid consisting only of a protic polar solvent or a rinsing liquid containing a protic polar solvent as the principal component; and a solvent. The water-repellent protective film forming agent is at least one kind of compound represented by the following general formulas [1] to [3].

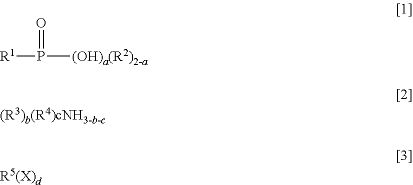

### TECHNICAL FIELD

The present invention relates to a technique for cleaning a substrate (a wafer) in semiconductor device fabrication and the like, and particularly to a liquid chemical for forming a water-repellent protective film

### BACKGROUND OF THE INVENTION

Semiconductor devices for use in networks or digital household electric appliances are desired to be further sophisticated, multifunctional, and low in power consumption. Accordingly, the trend toward micro-patterning for circuits has been developed, with which a pattern collapse of the circuits has been becoming controversial. In semiconductor device fabrication, cleaning steps for the purpose of removing particles and metallic impurities are frequently employed, which results in a 30-40% occupation of the whole of a semiconductor fabrication process by the cleaning step. If the aspect ratio of the pattern is increased with the trend toward micro-patterning of the semiconductor devices, the pattern is to cause its collapse when a gas-liquid interface passes therethrough after cleaning or rinsing at the time of drying the wafer. This phenomenon is pattern collapse.

Hitherto, a wafer containing silicon element at its surface has generally been used as the above-mentioned wafer; however, a wafer that contains an element other than silicon element at its surface has become used together with the diversification of the pattern. Patent Publication 1 discloses a liquid chemical for forming a water-repellent protective film on a wafer having at its surface a finely uneven pattern and containing at least at a part of surfaces of recessed portions of the uneven pattern at least one kind of matter selected from the group consisting of titanium, titanium nitride, tungsten, aluminum, copper, tin, tantalum nitride, ruthenium and silicon, the liquid chemical containing a water-insoluble surfactant that serves as a water-repellent protective film forming agent which is for forming a water-repellent protective film at least on the surfaces of the recessed portions.

### REFERENCES ABOUT PRIOR ART

### Patent Documents

Patent Publication 1: Japanese Patent No. 4743340

### SUMMARY OF THE INVENTION

### Problems to be Solved by the Invention

If conducing a treatment on a wafer surface containing at least one kind of matter selected from the group consisting of titanium, titanium nitride, tungsten, aluminum, copper, tin, tantalum nitride, ruthenium and silicon in the use of the liquid chemical for forming a water-repellent protective film of Patent Publication 1, a good water repellency is imparted to the surface. However, in the case of performing a rinsing treatment where a rinsing liquid containing a protic polar solvent generally usable in a wafer-cleaning process and superior in rinsing ability (such as water and alcohol) is retained on the surface that had been formed with a water-repellent protective film, the water repellency on the surface is sometimes reduced and therefor further improvements have been intended. An object of the present invention is to provide a liquid chemical for forming a water-repellent protective film on a wafer having at its surface an uneven pattern and containing at least one kind of element selected from the group consisting of titanium, tungsten, aluminum, copper, tin, tantalum and ruthenium (hereinafter, sometimes referred to as “metal-based elements”) at surfaces of recessed portions of the uneven pattern (hereinafter, the wafer may be referred to as “a metal-based wafer” or merely “a wafer”), the liquid chemical being capable of maintaining a sufficient water repellency of the surface even in the case where the surface is subjected to a rinsing treatment with a rinsing liquid containing a protic polar solvent after the water-repellent protective film is formed at least on the surfaces of the recessed portions of the wafer.

### Means for Solving the Problems

Pattern collapse is to occur when a gas-liquid interface passes through a pattern at the time of drying a wafer after cleaning it with a cleaning liquid. The reason therefor is said that a difference in height of residual liquid of the cleaning liquid between a part having high aspect ratio and a part having low aspect ratio causes a difference in capillary force which acts on the pattern.

Accordingly, it is expected, by decreasing the capillary force, that the difference in capillary force due to the difference in height of residual liquid is reduced thereby resulting in the dissolution of pattern collapse. The degree of the capillary force is the absolute value of P obtained by the equation as shown below. It is expected from this equation that the capillary force can be reduced by decreasing γ or cosθ.

P=2×γ×cosθ/S

(In the equation, γ represents the surface tension of liquid retained in the recessed portions, θ represents the contact angle of the liquid retained in the recessed portions to the surfaces of the recessed portions, and S represents the width of the recessed portions.)

In the present invention, when the rinsing liquid retained on the recessed portions after the water-repellent protective film has been formed is removed or dried out of the recessed portions, there exists the water-repellent protective film at least on the surfaces of the recessed portions of the uneven pattern. Therefore, the capillary force which acts on the recessed portions is so reduced that pattern collapse becomes difficult to occur. Additionally, the water-repellent protective film is to be removed after the rinsing liquid is removed.

A liquid chemical for forming a water-repellent protective film (hereinafter, sometimes referred to as “a liquid chemical for forming a protective film” or merely “a liquid chemical”) according to the present invention is a liquid chemical comprising: a water-repellent protective film forming agent for forming a water-repellent protective film on a wafer (hereinafter, sometimes referred to as merely “a protective film forming agent”) having at its surface an uneven pattern and containing at least one kind of element selected from the group consisting of titanium, tungsten, aluminum, copper, tin, tantalum and ruthenium at surfaces of recessed portions of the uneven pattern, the water-repellent protective film (hereinafter, sometimes referred to as merely “a protective film”) being formed at least on the surfaces of the recessed portions by retaining the liquid chemical at least on the recessed portions of the wafer before a rinsing treatment step of rinsing the wafer surface with a rinsing liquid consisting only of a protic polar solvent or a rinsing liquid containing a protic polar solvent as the principal component; and a solvent, the liquid chemical being characterized in that the water-repellent protective film forming agent is at least one kind of compound represented by the following general formulas [1] to [3].

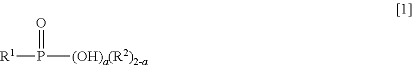

(In the formula [1], R⁴ represents a C₆-C₁₈ monovalent hydrocarbon group the hydrogen elements of which may partially or entirely be replaced with a fluorine element(s), R² mutually independently represents a monovalent organic group having a C₁-C₁₈ hydrocarbon group the hydrogen elements of which may partially or entirely be replaced with a fluorine element(s), and “a” is an integer of from 0 to 2.)

(R³)_{b}(R⁴)_{c}NH_{3-b-c} [2]

(In the formula [2], R³ mutually independently represents a C₆-C₁₈ monovalent hydrocarbon group the hydrogen elements of which may partially or entirely be replaced with a fluorine element(s), R⁴ mutually independently represents a C₁-C₃ monovalent hydrocarbon group the hydrogen elements of which may partially or entirely be replaced with a fluorine element(s), “b” is an integer of from 1 to 3, “c” is an integer of from 0 to 2, and the total of “b” and “c” is an integer of from 1 to 3.)

R⁵(X)_{d} [3]

(The formula [3] represents a compound obtained by mutually independently substituting “d” hydrogen element(s) or fluorine element(s) of R⁵ which represents a C₄-C₁₈ hydrocarbon the hydrogen elements of which may partially or entirely be replaced with a fluorine element(s) with at least one group indicated by X and selected from the group consisting of an isocyanate group, mercapto group, —CONHOH group and a cyclic structure containing a nitrogen element, wherein “d” is an integer of from 1 to 6.)

By using the protective film forming agent represented by the general formulas [1] to [3], it becomes possible to form a water-repellent protective film at least on the surfaces of the recessed portions of the metal-based wafer. The protective film forming agent has compatibility with a substance containing the above-mentioned metal-based elements, at a functional group represented by P—OH and/or P═O in the general formula [1], or at a functional group represented by NH_{3-b-c} in the general formula [2], or at a functional group represented by X in the general formula [3] (hereinafter, these functional groups may generically be referred to as “a functional moiety”). Incidentally, “have compatibility” means that Van der Waals force, a static interaction or the like acts between the surface of the substance containing the metal-based elements and the functional moiety of the protective film forming agent thereby causing physical adsorption and/or that the surface of the substance is reacted with the functional moiety of the protective film forming agent to build a chemical bond thereby causing chemical adsorption. Hereinafter, the above-mentioned “physical adsorption” and “chemical adsorption” may generically be referred to as merely “adsorption”. Additionally, R¹, R³ and R⁵ are hydrophobic moieties of the protective film forming agent; therefore, when the protective film forming agent is adsorbed on the metal-based elements in a metal-based wafer, the hydrophobic moieties are arranged outwardly from the surface of the wafer thereby imparting water repellency to the wafer surface. Furthermore, R¹ and R³ are C₆-C₁₈ hydrocarbon groups while R⁵ is a C₄-C₁₈ hydrocarbon. Since these hydrocarbon groups (hydrocarbon) are hydrocarbon groups the hydrogen elements of which may partially or entirely be replaced with a fluorine element(s), it becomes possible to impart a sufficient water repellency to the surface of the metal-based wafer, and additionally the sufficient water repellency on the surface can easily be maintained even after carrying out a rinsing treatment where a rinsing liquid consisting only of a protic polar solvent such as water and alcohol or a rinsing liquid containing the protic polar solvent as the principal component is retained on the surface that had undergone the water-repellent protective film forming step. Incidentally, the effect of easily maintaining a sufficient water repellency after the above-mentioned rinsing treatment may sometimes be referred to as “a rinsing resistance”.

It is preferable that “a” in the general formula [1] is 2. Such a compound is preferably used as the water-repellent protective film forming agent because a better water repellency and a better rinsing resistance are provided.

Moreover, R¹ in the general formula [1] is preferably a C₈-C₁₈ monovalent hydrocarbon group the hydrogen elements of which may partially or entirely be replaced with a fluorine element(s). It is preferable to use such a compound as the water-repellent protective film forming agent since a better water repellency and a better rinsing resistance are obtained thereby.

Furthermore, it is preferable that “b” in the general formula [2] is 1. It is preferable to use such a compound as the water-repellent protective film forming agent since steric hindrance to be caused when the functional group is adsorbed on the metal surface is little. Additionally, “c” in the general formula [2] is preferably 0.

Moreover, R³ in the general formula [2] is preferably a C₈-C₁₈ monovalent hydrocarbon group the hydrogen elements of which may partially or entirely be replaced with a fluorine element(s). It is preferable to use such a compound as the water-repellent protective film forming agent since a better water repellency and a better rinsing resistance can be provided thereby.

In addition, R⁵ in the general formula [3] preferably has a carbon number of 6 to 18. It is preferable to use such a compound as the water-repellent protective film forming agent since a better water repellency and a better rinsing resistance can be provided, and additionally the water repellency is difficult to be reduced by the rinsing treatment.

As the above-mentioned metal-based wafer, it is possible to cite: a wafer containing at least one kind of element selected from the group consisting of titanium, tungsten, aluminum, copper, tin, tantalum and ruthenium at the surfaces of the recessed portions of the uneven pattern: preferably a wafer containing at least one kind of element selected from the group consisting of titanium, tungsten, aluminum and ruthenium: particularly preferably a wafer containing at least one kind of element selected from the group consisting of titanium, tungsten and ruthenium. In a case of a wafer containing silicon element at the surfaces of the recessed portions of the uneven pattern, there are a great number of silanol groups (SiOH groups) on the surfaces. These silanol groups serve as reaction points to be reacted with a silane coupling agent, so that the water-repellent protective film can easily be formed on the surfaces of the recessed portions. On the other hand, in a case of the metal-based wafer, its surface has fewer reaction points such as the silanol groups and therefore it is difficult to form the protective film by a compound such as the silane coupling agent. Additionally, in the present invention, “a wafer having at its surface an uneven pattern” means a wafer which is in a condition where the uneven pattern has already been formed on the surface by etching, imprint or the like. Moreover, it is possible to adopt a wafer on which another process such as metal routing has been performed, as far as the wafer has an uneven pattern at its surface.

The liquid chemical for forming a protective film, according to the present invention is used in a process of cleaning the metal-based wafer in such a manner as to substitute a rinsing liquid retained on the wafer surface with the liquid chemical. After forming the protective film, the liquid chemical is substituted with a rinsing liquid consisting only of a protic polar solvent or a rinsing liquid containing a protic polar solvent as the principal component.

A water-repellent protective film according to the present invention is a water-repellent protective film formed on a wafer having at its surface an uneven pattern and containing at least one kind of element selected from the group consisting of titanium, tungsten, aluminum, copper, tin, tantalum and ruthenium at surfaces of recessed portions of the uneven pattern, the water-repellent protective film being formed at least on the surfaces of the recessed portions by retaining the liquid chemical for forming water-repellent protective film at least on the recessed portions before a rinsing treatment step of rinsing the wafer surface with a rinsing liquid consisting only of a protic polar solvent or a rinsing liquid containing a protic polar solvent as the principal component, characterized in that the water-repellent protective film is formed of at least one kind of compounds that serve as the water-repellent protective film forming agent and represented by the general formulas [1] to [3]. Incidentally, the water-repellent protective film may include a reactant containing as the principal component at least one kind of compounds represented by the general formulas [1] to [3].

While the cleaning liquid is substituted with the liquid chemical for forming a protective film after the cleaning step and the liquid chemical is retained at least in the recessed portions of the uneven pattern as discussed above, the protective film is formed at least on the surfaces of the recessed portions of the uneven pattern. The protective film of the present invention may not necessarily continuously be formed and may not necessarily uniformly be formed. However, in order to impart more excellent water repellency, it is more preferable to form the protective film continuously and uniformly.

In the present invention, the protective film means a film that can reduce the wettability of the wafer surface by being formed on the wafer surface, and more specifically, a film which is able to impart water repellency to the same. In the present invention, water repellency means to decrease a surface energy of a surface of an article thereby weakening the interaction (such as a hydrogen bond, intermolecular forces and the like) between water or other liquid and the surface of the article (i.e., at the interface). The effect of reducing the interaction is particularly exhibited in the case of water, but the effect of reducing the interaction is exhibited also in the case of a mixture liquid of water and a liquid other than water or in the case of a liquid other than water. With such a reduction of the interaction, the contact angle of liquid to the article surface can be increased.

A method of cleaning a wafer, according to the present invention is a method of cleaning a wafer having at its surface an uneven pattern and containing at least one kind of element selected from the group consisting of titanium, tungsten, aluminum, copper, tin, tantalum and ruthenium at surfaces of recessed portions of the uneven pattern, characterized by comprising at least the steps of:

a water-repellent protective film forming step for retaining a liquid chemical for forming a water-repellent protective film at least in the recessed portions of the uneven pattern:

a rinsing treatment step of retaining a rinsing liquid consisting only of a protic polar solvent or a rinsing liquid containing a protic polar solvent as the principal component, on the wafer surface that had undergone the water-repellent protective film forming step:

a rinsing liquid removal step for removing the rinsing liquid: and

a water-repellent protective film removal step for removing a water-repellent protective film:

wherein the liquid chemical for forming a water-repellent protective film is a liquid chemical comprising a water-repellent protective film forming agent for forming a water-repellent protective film at least on the surfaces of the recessed portions, and the water-repellent protective film forming agent is at least one kind of compound represented by the general formulas [1] to [3].

Additionally, the protic polar solvent is preferably an alcohol.

In addition, the water-repellent protective film forming step is preferably such as to remove the water-repellent protective film by performing at least one treatment selected from the group consisting of: irradiating the wafer surface with light: heating the wafer: exposing the wafer to ozone: irradiating the wafer surface with plasma: and subjecting the wafer surface to corona discharge.

### EFFECTS OF THE INVENTION

The liquid chemical for forming a water-repellent protective film, according to the present invention is able to form a water-repellent protective film on the surface of a metal-based wafer, thereby imparting an excellent water repellency to the wafer surface. In addition, a sufficient water repellency can easily be maintained even after a rinsing treatment where a rinsing liquid containing a protic polar solvent such as water and alcohol is retained on the surface that had been subjected to a water-repellent protective film formation is performed. Hence a cleaning method that involves the above-mentioned rinsing treatment can reduce the interaction between the rinsing liquid and the wafer surface thereby exhibiting the effect of preventing pattern collapse. By using the liquid chemical, a cleaning step conducted in a process for producing the metal-based wafer having at its surface an uneven pattern is improved without lowering throughput. Accordingly, the process for producing the metal-based wafer having the uneven pattern at its surface, performed with use of the liquid chemical for forming a protective film of to the present invention, is provided excellently in productivity.

The liquid chemical for forming a water-repellent protective film, according to the present invention is adaptable to uneven patterns having an aspect ratio expected to rise more and more in the future, for example, an aspect ratio of not less than 7, which allows cost reduction in producing more sophisticated semiconductor devices. In addition, the liquid chemical is adaptable without largely modifying conventional apparatuses and therefore results in being one applicable in production of various kinds of semiconductor devices.

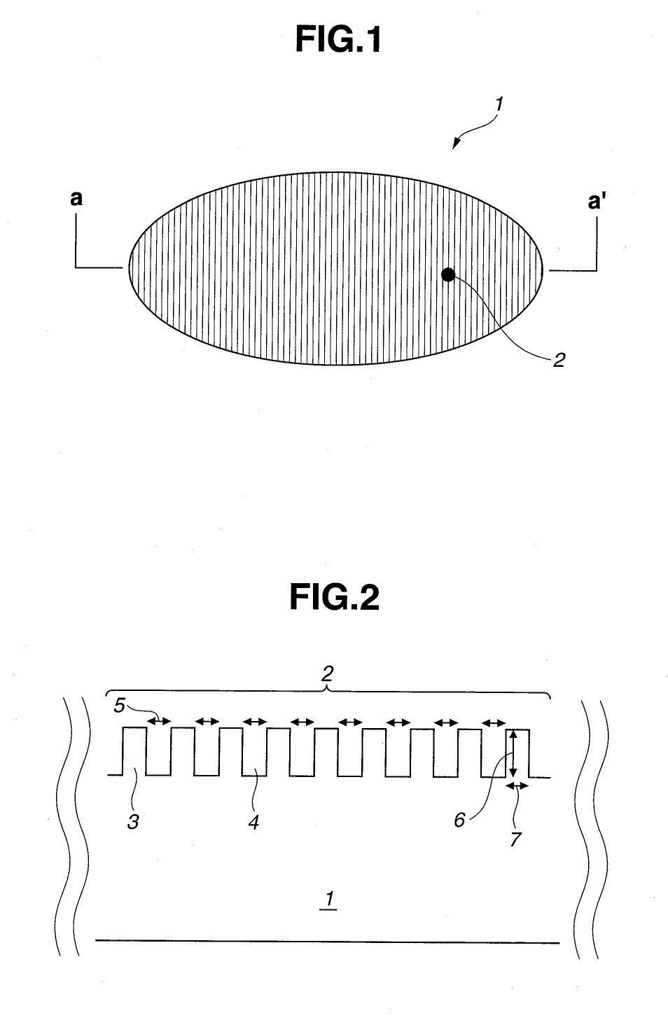

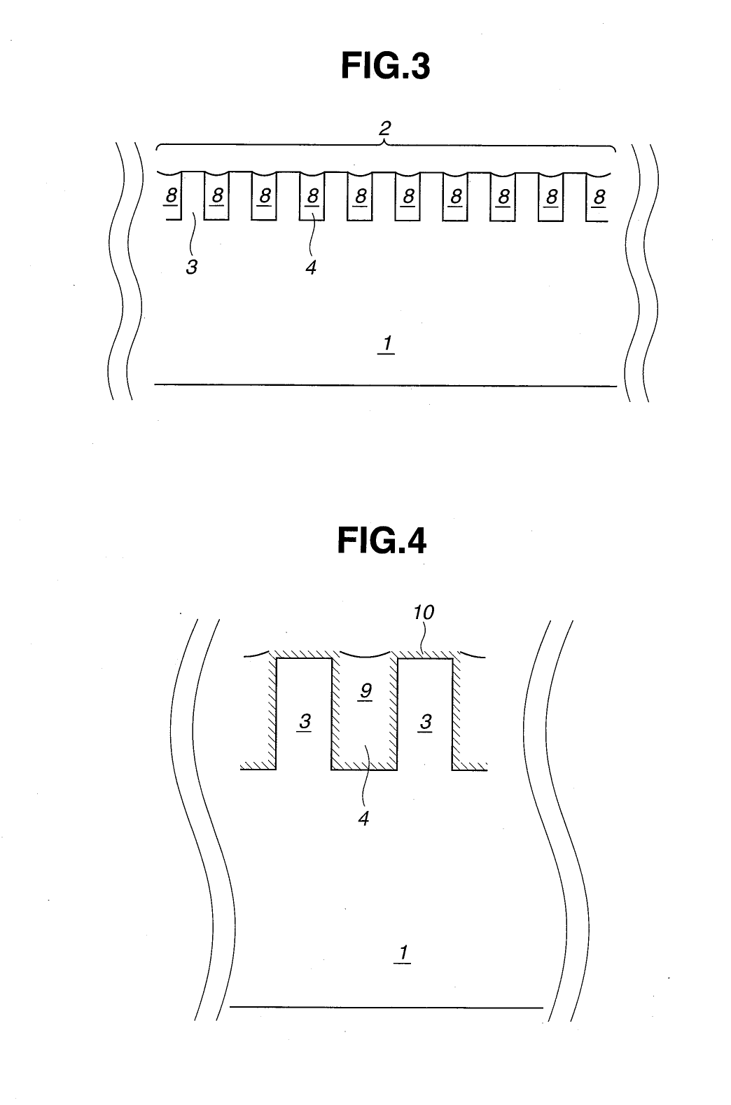

### BRIEF DESCRIPTION OF THE DRAWINGS

[FIG. 1] A schematic perspective view of a wafer 1 the surface of which has an uneven pattern 2.

[FIG. 2] A schematic view showing a part of a-a′ cross section of FIG. 1.

[FIG. 3] A schematic view showing a condition where a liquid chemical 8 for forming a water-repellent protective film is retained in recessed portions 4 in a cleaning process.

[FIG. 4] A schematic view showing a condition where a rinsing liquid is retained in the recessed portions 4 on which a water-repellent protective film is formed.

### MODE(S) FOR CARRYING OUT THE INVENTION

As a metal-based wafer, it is possible to cite: those obtained by coating a surface of a silicon wafer, a wafer formed of a plurality of components including silicon and/or silicon oxide (SiO₂), a silicon carbide wafer, a sapphire wafer, various compound semiconductor wafers, a plastic wafer or the like with a layer formed of a matter containing titanium element such as titanium, titanium nitride and titanium oxide, a matter containing tungsten element such as tungsten, tungsten oxide and the like, a matter containing aluminum element such as aluminum and aluminum oxide, a matter containing copper element such as copper and copper oxide, a matter containing tin element such as tin and tin oxide, a matter containing tantalum element such as tantalum nitride and tantalum oxide, or a matter containing ruthenium element such as ruthenium and ruthenium oxide: those in which at least one layer of a multilayer film formed on the wafer is a layer formed of a matter containing the above-mentioned metal-based elements: and the like. A step of forming the uneven pattern is conducted on a layer including a layer formed of the matter containing the above-mentioned metal-based elements. Additionally, those in which at least a part of the surfaces of the recessed portions serves as a matter containing at least one kind of the above-mentioned metal-based elements at the time of forming the uneven pattern are also included.

In general, pretreatment steps are performed previous to conducting a surface treatment using a liquid chemical for forming a protective film of the present invention. The pretreatment steps are exemplified as follows:

a pretreatment step 1 of making a wafer surface into a surface having an uneven pattern:

a pretreatment step 2 of cleaning the wafer surface by using a water-based cleaning liquid: and

a pretreatment step 3 of substituting the water-based cleaning liquid with a cleaning liquid A different from the water-based cleaning liquid (hereinafter, sometimes referred to as merely “a cleaning liquid A”).

Incidentally, either the pretreatment step 2 or the pretreatment step 3 may be skipped in some cases.

An example of a method of forming a pattern in the pretreatment step 1 will be discussed. First of all, a resist is applied to the wafer surface. Thereafter, the resist is exposed through a resist mask, followed by conducting an etching removal on the exposed resist or an unexposed resist, thereby producing a resist having a desired uneven pattern. Additionally, the resist having an uneven pattern can be obtained also by pressing a mold having a pattern onto the resist. Then, the wafer is subjected to etching. At this time, the ₚarts of the wafer surface which parts correspond to recessed portions of a resist pattern are etched selectively. Finally, the resist is stripped off thereby obtaining a wafer having an uneven pattern. Incidentally, the pattern-forming method is not limited to the above one.

By the above-mentioned pretreatment step 1, it becomes possible to obtain a wafer having at its surface an uneven pattern and containing at least one kind of element selected from the group consisting of titanium, tungsten, aluminum, copper, tin, tantalum and ruthenium at surfaces of recessed portions of the uneven pattern.

Examples of the water-based cleaning liquid used in the pretreatment step 2 are water and an aqueous solution obtained by mixing at least one kind of an organic solvent, hydrogen peroxide, ozone, acid, alkali and surfactant with water (the aqueous solution having a water content of not less than 10 mass %, for example).

Furthermore, in the pretreatment step 2, substitution with the water-based cleaning liquid may be conducted twice or more. The water-based cleaning liquids to be used in this case may be different from each other.

If recessed portions have a small width and projected portions have a large aspect ratio, and if the surface is cleaned with the water-based cleaning liquid in the pretreatment step 2 and subsequently the water-based cleaning liquid is removed by drying and the like or if water is removed by drying and the like after substituting the water-based cleaning liquid with water, a pattern collapse is to easily occur. The uneven pattern is defined as shown in FIG. 1 and FIG. 2. FIG. 1 is one example of a schematic perspective view of a wafer 1 the surface of which has an uneven pattern 2. FIG. 2 shows a part of a-a′ cross section of FIG. 1. A width 5 of recessed portions is defined by an interval between a projected portion 3 and a projected portion 3, as shown in FIG. 2. The aspect ratio of projected portions is expressed by dividing a height 6 of the projected portions by a width 7 of the projected portions. Pattern collapse in the cleaning step is to easily occur when the recessed portions have a width of not more than 70 nm, particularly not more than 45 nm and when the aspect ratio is not less than 4, particularly not less than 6.

The cleaning liquid A used in the pretreatment step 3 refers to an organic solvent, a mixture of the organic solvent and a water-based cleaning liquid, or a cleaning liquid into which at least one kind of acid, alkali and surfactant is mixed with these. Furthermore, it is preferable to carry out a step of retaining the liquid chemical for forming a protective film at least in the recessed portions of the uneven pattern (i.e. a water-repellent protective film forming step) by substituting the cleaning liquid A with the liquid chemical for forming a protective film of the present invention.

In the present invention, a style for cleaning the wafer is not particularly limited so long as the liquid chemical or the cleaning liquid or the rinsing liquid can be retained at least in the recessed portions of the uneven pattern of the wafer. Examples of the style for cleaning the wafer are: a single cleaning style represented by spin cleaning where a generally horizontally held wafer is rotated and cleaned one by one while supplying a liquid to the vicinity of the center of the rotation: and a batch style where a plurality of wafer sheets are immersed in a cleaning bath to be cleaned. Incidentally, the form of the liquid chemical or the cleaning liquid or the rinsing liquid at the time of supplying the liquid chemical or the cleaning liquid or the rinsing liquid at least to the recessed portions of the uneven pattern of the wafer is not particularly limited as far as it is in a condition of liquid at time of being retained in the recessed portions, and is exemplified by liquid, vapor or the like.

The organic solvent, which is one preferable example of the cleaning liquid A, is exemplified by hydrocarbons, esters, ethers, ketones, halogen element-containing solvents, sulfoxide-based solvents, lactone-based solvents, carbonate-based solvents, alcohols, polyalcohol derivatives having OH group, polyalcohol derivatives having no OH group, nitrogen element-containing solvents and the like.

Examples of hydrocarbons are toluene, benzene, xylene, hexane, heptane, octane and the like. Examples of esters are ethyl acetate, propyl acetate, butyl acetate, ethyl acetoacetate and the like. Examples of ethers are diethyl ether, dipropyl ether, dibutyl ether, tetrahydrofuran, dioxane and the like. Examples of ketones are acetone, acetylacetone, methyl ethyl ketone, methyl propyl ketone, methyl butyl ketone, cyclohexanone and the like. Examples of the halogen element-containing solvents are: perfluorocarbons such as perfluorooctane, perfluorononane, perfluorocyclopentane, perfluorocyclohexane, hexafluorobenzene and the like: hydrofluorocarbons such as 1,1,1,3,3-pentafluorobutane, octafluorocyclopentane, 2,3-dihydrodecafluoropentane, ZEORORA-H (produced by ZEON CORPORATION) and the like: hydrofluoroethers such as methyl perfluoroisobutyl ether, methyl perfluorobutyl ether, ethyl perfluorobutyl ether, ethyl perfluoroisobutyl ether, ASAHIKLIN AE-3000 (produced by Asahi Glass Co., Ltd.), Novec 7100, Novec 7200, Novec 7300, Novec 7600 (any of these are produced by 3M Limited) and the like: chlorocarbons such as tetrachloromethane and the like: hydrochlorocarbons such as chloroform and the like: chlorofluorocarbons such as dichlorodifluoromethane and the like:

hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene, 1,2-dichloro-3,3,3-trifuoropropene and the like: perfluoroethers: perfluoropolyethers: and the like. Examples of the sulfoxide-based solvents are dimethyl sulfoxide and the like. Examples of the lactone-based solvents are γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone and the like. Examples of the carbonate-based solvents are dimethyl carbonate, ethyl methyl carbonate, diethyl carbonate, propylene carbonate and the like. Examples of alcohols are methanol, ethanol, propanol, butanol, ethylene glycol, diethylene glycol, 1,2-propanediol, 1,3-propanediol, dipropylene glycol, 1,2-butanediol, 1,3-butanediol, 1,4-butanediol, triethylene glycol, tripropylene glycol, tetraethylene glycol, tetrapropylene glycol, glycerine and the like. Examples of the polyalcohol derivatives having OH group are ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether, diethylene glycol monobutyl ether, triethylene glycol monomethyl ether, triethylene glycol monoethyl ether, triethylene glycol monopropyl ether, triethylene glycol monobutyl ether, tetraethylene glycol monomethyl ether, tetraethylene glycol monoethyl ether, tetraethylene glycol monopropyl ether, tetraethylene glycol monobutyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tripropylene glycol monoethyl ether, tripropylene glycol monopropyl ether, tripropylene glycol monobutyl ether, tetrapropylene glycol monomethyl ether, butylene glycol monomethyl ether and the like. Examples of the polyalcohol derivatives having no OH group are ethylene glycol dimethyl ether, ethylene glycol diethyl ether, ethylene glycol dibutyl ether, ethylene glycol monomethyl ether acetate, ethylene glycol monoethyl ether acetate, ethylene glycol monobutyl ether acetate, ethylene glycol diacetate, diethylene glycol dimethyl ether, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol dimethyl ether, propylene glycol diethyl ether, propylene glycol dibutyl ether, propylene glycol monomethyl ether acetate, propylene glycol monoethyl ether acetate, propylene glycol monobutyl ether acetate, propylene glycol diacetate, dipropylene glycol dimethyl ether, dipropylene glycol methyl propyl ether, dipropylene glycol diethyl ether, dipropylene glycol dibutyl ether, dipropylene glycol monomethyl ether acetate, dipropylene glycol monoethyl ether acetate, dipropylene glycol monobutyl ether acetate, dipropylene glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol dimethyl ether, butylene glycol monomethyl ether acetate, butylene glycol diacetate, glycerine triacetate and the like. Examples of the nitrogen element-containing solvents are formamide, N,N-dimethylformamide, N,N-dimethylacetamide, N-methyl-2-pyrrolidone, diethylamine, triethylamine, pyridine and the like.

Incidentally, it is preferable that the cleaning liquid A is an organic solvent or a mixture liquid of water and an organic solvent in view of its cleanliness. Furthermore, it is preferable that the organic solvent contains a water-soluble organic solvent (a solubility in water is not smaller than 5 mass parts by mass relative to 100 parts by mass of water) because it can be easily substituted for the water-based cleaning liquid.

Additionally, in the pretreatment step 3, substitution with the cleaning liquid A may be conducted twice or more. More specifically, the water-based cleaning liquid used in the pretreatment step 2 may be substituted with a first kind of cleaning liquid A and then the first kind of cleaning liquid A may be substituted successively with two or more kinds of cleaning liquids A different from the above-mentioned cleaning liquid A, and finally it may be substituted with the liquid chemical for forming a protective film.

Moreover, in a case where the water-based cleaning liquid used in the pretreatment step 2 can be substituted directly with the liquid chemical for forming a protective film, substitution with the cleaning liquid A (the pretreatment step 3) may be skipped.

FIG. 3 is a schematic view showing a condition in which a liquid chemical 8 for forming a protective film is retained in recessed portions 4 in a protective film-forming step. The wafer of the schematic view of FIG. 3 shows a part of the a-a′ cross section in FIG. 1. At this time, the protective film forming agent is adsorbed onto the surfaces of the recessed portions 4, thereby forming a protective film and imparting water repellency to the surfaces.

Incidentally, where the protective film can be formed by using the liquid chemical of the present invention is at least on a surface of a portion of a matter containing at least one kind of the metal-based elements, in the uneven pattern. Accordingly, the protective film may be such as to be formed at least on a part of the surfaces of the recessed portions of the metal-based wafer. Additionally, also in the case of a wafer formed of a plurality of components including the matter containing at least one kind of the above-mentioned metal-based elements, it is possible to form the protective film on the surface of the matter containing at least one kind of the above-mentioned metal-based elements. As examples of the wafer formed of a plurality of components, there are further included: those in which the matter containing at least one kind of the above-mentioned metal-based elements is formed at least at a part of the surfaces of the recessed portions: and those in which at least a part of the surfaces of the recessed portions consists of the matter containing at least one kind of the above-mentioned metal-based elements at the time of forming the uneven pattern.

Incidentally, the liquid chemical for forming a protective film, according to the present invention can easily form an excellently water-repellent protective film on the surface of an article containing at least one kind of element selected from titanium, tungsten and ruthenium at its surface. Therefore, it is preferable that the wafer is a wafer having at its surface an uneven pattern and containing at least one kind of element selected from titanium, tungsten and ruthenium at the surfaces of the recessed portions of the uneven pattern.

The liquid chemical for forming a protective film is a liquid chemical comprising: a protective film forming agent for forming a protective film at least on the surfaces of the recessed portions of a metal-based wafer by retaining the liquid chemical at least on the recessed portions of the wafer before a rinsing treatment step of rinsing the surface of the metal-based wafer with a rinsing liquid consisting only of a protic polar solvent or a rinsing liquid containing a protic polar solvent as the principal component: and a solvent, wherein the water-repellent protective film forming agent is at least one kind of compound represented by the general formulas [1] to [3].

A hydrocarbon group contained in R² of the general formula [1] is exemplified by alkyl group, alkylene group and those the hydrogen elements of which are partially or entirely replaced with a fluorine element(s).

Additionally, it is preferable that the above-mentioned R² is —OR⁶ (where R⁶ is a C₁-C₁₈ hydrocarbon group). Additionally, it is preferable that R⁶ has a carbon number of 1 to 8, particularly 1 to 4, since a more excellent water repellency is imparted thereby. Moreover, R⁶ is preferably a straight-chained alkyl group.

As the compound represented by the general formula [1], it is possible to cite C₆H₁₃P(O)(OH)₂, C₇H₁₅P(O)(OH)₂, C₈H₁₇P(O)(OH)₂, C₉H₁₉P(O)(OH)₂, C₁₀H₂₇P(O)(OH)₂, C₁₁H₂₃P(O)(OH)₂, C₁₂H₂₅P(O)(OH)₂, C₁₃H₂₇P(O)(OH)₂, C₁₄H₂₉P(O)(OH)₂, C₁₅H₃₁P(O)(OH)₂, C₁₆H₃₃P(O)(OH)₂, C₁₇H₃₅P(O)(OH)₂, C₁₈H₃₇P(O)(OH)₂, C₆H₅P(O)(OH)₂, C₅F₁₃P(O)(OH)₂, C₇F₁₅P(O)(OH)₂, C₈F₁₇P(O)(OH)₂, C₄F₉C₂H₄P(O)(OH)₂, C₅F₁₁C₂H₄P(O)(OH)₂, C₆F₁₃C₂H₄P(O)(OH)₂, C₇F₁₅C₂H₄P(O)(OH)₂, C₈F₁₇C₂H₄P(O)(OH)₂, and compounds obtained by substituting —P(O)(OH)₂ group of the above compounds with —P(O)(OH)OCH₃ group, —P(O)(OH)OC₂H₅ group, —P(O)(OCH₃)₂ group or —P(O)(OC₂H₅)₂ group.

It is preferable to use a compound where “a” in the general formula [1] is 1 or 2 as the water-repellent protective film forming agent, since a better water repellency can be provided thereby. Furthermore, a compound where “a” is 2, represented by the following general formula [4], is more preferably used because a better water repellency and a better rinsing resistance can be provided thereby.

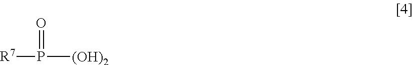

(In the formula [4], R⁷ represents a C₆-C₁₈ monovalent hydrocarbon group the hydrogen elements of which may partially or entirely be replaced with a fluorine element(s).)

The protective film forming agent may exist in the form of a salt of the compound represented by the general formulas [1] and [4], such as ammonium salt, amine salt and the like.

As the compound represented by the general formula [2], it is possible to cite compounds such as C₆H₁₃NH₂, C₇H₁₅NH₂, C₈H₁₇NH₂, C₉H₁₉NH₂, C₁₀H₂₁NH₂, C₁₁H₃₃NH₂, C₁₂H₂₅NH₂, C₁₃H₂₇NH₂, C₁₄H₂₉NH₂, C₁₅H₃₁NH₂, C₁₆H₃₃NH₂, C₁₇H₃₅NH₂, C₁₈H₃₇NH₂, C₆F₁₃NH₂, C₇F₁₅NH₂, C₈F₁₇NH₂, C₉F₁₉NH₂, C₁₀F₂₁NH₂, C₁₁F₂₃NH₂, C₁₂F₂₅NH₂, C₁₃F₂₇NH₂, C₁₄F₂₉NH₂, C₁₅F₃₁NH₂, C₁₆F₃₃NH₂, C₁₇F₃₅NH₂, C₁₈F₃₇NH₂, C₆F₁₁H₂NH₂, C₇F₁₃H₂NH₂, C₈F₁₅H₂NH₂, C₉F₁₇H₂NH₂, C₁₀F₁₉H₂NH₂, C₁₁F₂₁H₂NH₂, C₁₂F₂₃H₂NH₂, C₁₃F₂₅H₂NH₂, C₁₄F₂₇H₂NH₂, C₁₅F₂₉H₂NH₂, C₁₆F₃₁H₂NH₂, C₁₇F₃₃H₂NH₂, C₁₈F₃₅H₂NH₂, C₆F₉H₄NH₂, C₇F₁₁H₄NH₂, C₈F₁₃N₄NH₂, C₉F₁₅H₄NH₂, C₁₀F₁₇H₄NH₂, C₁₁F₁₉H₄NH₂, C₁₂F₂₁H₄NH₂, C₁₃F₂₃H₄NH₂, C₁₄F₂₅H₄NH₂, C₁₅F₂₇H₄NH₂, C₁₆F₂₉H₄NH₂, C₁₇F₃₁H₄NH₂, C₁₈F₃₃H₄NH₂, (C₆H₁₃)₂NH, (C₇H₁₅)₂NH, (C₈H₁₇)₂NH, (C₉H₁₉)₂NH, (C₁₀H₂₁)₂NH, (C₁₁H₂₃)₂NH, (C₁₂H₂₅)₂NH, (C₁₃H₂₇)₂NH, (C₁₄H₂₉)₂NH, (C₁₅H₃₁)₂NH, (C₁₆H₃₃)₂NH, (C₁₇H₃₅)₂NH, (C₁₈H₃₇)₂NH, (C₆F₁₃)₂NH, (C₇F₁₅)₂NH, (C₈F₁₇)₂NH, (C₉F₁₉)₂NH, (C₁₀F₂₁)₂NH, (C₁₁F₂₃)₂NH, (C₁₂F₂₅)₂NH, (C₁₃F₂₇)₂NH, (C₁₄F₂₉)₂NH, (C₁₅F₃₁)₂NH, (C₁₆F₃₃)₂NH, (C₁₇F₃₅)₂NH, (C₁₈F₃₇)₂NH, (C₆F₁₁H₂)₂NH, (C₇F₁₃H₂)₂NH, (C₈F₁₅H₂)₂NH, (C₉F₁₇H₂)₂NH, (C₁₀F₁₉H₂)₂NH, (C₁₁F₂₁H₂)₂NH, (C₁₂F₂₃H₂)₂NH, (C₁₃F₂₅H₂)₂NH, (C₁₄F₂₇H₂)₂NH, (C₁₅F₂₉H₂)₂NH, (C₁₆F₃₁H₂)₂NH, (C₁₇F₃₃H₂)₂NH, (C₁₈F₃₅H₂)₂NH, (C₆F₉H₄)₂NH, (C₇F₁₁H₄)₂NH, (C₈F₁₃H₄)₂NH, (C₉F₁₅H₄)₂NH, (C₁₀F₁₇H₄)₂NH, (C₁₁F₁₉H₄)₂NH, (C₁₂F₂₁H₄)₂NH, (C₁₃F₂₃H₄)₂NH, (C₁₄F₂₅H₄)₂NH, (C₁₅F₂₇H₄)₂NH, (C₁₆F₂₉H₄)₂NH, (C₁₇F₃₁H₄)₂NH, (C₁₈F₃₃H₄)₂NH, (C₆H₁₃)₃N, (C₇H₁₅)₃N, (C₈H₁₇)₃N, (C₉H₁₉)₃N, (C₁₀H₂₁)₃N, (C₁₁H₂₃)₃N, (C₁₂H₂₅)₃N, (C₁₃H₂₇)₃N, (C₁₄H₂₉)₃N, (C₁₅H₃₁)₃N, (C₁₆H₃₃)₃N, (C₁₇H₃₅)₃N, (C₁₈H₃₇)₃N, (C₆F₁₃)₃N, (C₇F₁₅)₃N, (C₈F₁₇)₃N, (C₉F₁₉)₃N, (C₁₀F₂₁)₃N, (C₁₁F₂₃)₃N, (C₁₂F₂₅)₃N, (C₁₃F₂₇)₃N, (C₁₄F₂₉)₃N, (C₁₅F₃₁)₃N, (C₁₆F₃₃)₃N, (C₁₇F₃₅)₃N, (C₁₈F₃₇)₃N, (C₆F₁₁H₂)₃N, (C₇F₁₃H₂)₃N, (C₈F₁₅H₂)₃N, (C₉F₁₇H₂)₃N, (C₁₀F₁₉H₂)₃N, (C₁₁F₂₁H₂)₃N, (C₁₂F₂₃H₂)₃N, (C₁₃F₂₅H₂)₃N, (C₁₄F₂₇H₂)₃N, (C₁₅F₂₉H₂)₃N, (C₁₆F₃₁H₂)₃N, (C₁₇F₃₃H₂)₃N, (C₁₈F₃₅H₂)₃N, (C₆F₉H₄)₃N, (C₇F₁₁H₄)₃N, (C₈F₁₃H₄)₃N, (C₉F₁₅H₄)₃N, (C₁₀F₁₇H₄)₃N, (C₁₁F₁₉H₄)₃N, (C₁₂F₂₁H₄)₃N, (C₁₃F₂₃H₄)₃N, (C₁₄F₂₅H₄)₃N, (C₁₅F₂₇H₄)₃N, (C₁₆F₂₉H₄)₃N, (C₁₇F₃₁H₄)₃N, (C₁₈F₃₃H₄)₃N, (C₆H₁₃)(CH₃)NH, (C₇H₁₅)(CH₃)NH, (C₈H₁₇)(CH₃)NH, (C₉H₁₉)(CH₃)NH, (C₁₀H₂₁)(CH₃)NH, (C₁₁H₂₃)(CH₃)NH, (C₁₂H₂₅)(CH₃)NH, (C₁₃H₂₇)(CH₃)NH, (C₁₄H₂₉)(CH₃)NH, (C₁₅H₃₁)(CH₃)NH, (C₁₆H₃₃)(CH₃)NH, (C₁₇H₃₅)(CH₃)NH, (C₁₈H₃₇)(CH₃)NH, (C₆F₁₃)(CH₃)NH, (C₇F₁₅)(CH₃)NH, (C₈F₁₇(CH₃)NH, (C₉F₁₉)(CH₃)NH, (C₁₀F₂₁)(CH₃)NH, (C₁₁F₂₃)(CH₃)NH, (C₁₂F₂₅)(CH₃)NH, (C₁₃F₂₇)(CH₃)NH, (C₁₄F₂₉)(CH₃)NH, (C₁₅F₃₁)(CH₃)NH, (C₁₆F₃₃)(CH₃)NH, (C₁₇F₃₅)(CH₃)NH, (C₁₈F₃₇(CH₃)NH, (C₆H₁₃)(CH₃)₂N, (C₇H₁₅)(CH₃)₂N, (C₈H₁₇)(CH₃)₂N, (C₉H₁₉)(CH₃)₂N, (C₁₀H₂₁)(CH₃)₂N, (C₁₁H₂₃)(CH₃)₂N, (C₁₂H₂₅)(CH₃)₂N, (C₁₃H₂₇)(CH₃)₂N, (C₁₄H₂₉)(CH₃)₂N, (C₁₅H₃₁)(CH₃)₂N, (C₁₆H₃₃)(CH₃)₂N, (C₁₇H₃₅)(CH₃)₂N, (C₁₈H₃₇)(CH₃)₂N, (C₆F₁₃)(CH₃)₂N, (C₇F₁₅)(CH₃)₂N, (C₈F₁₇)(CH₃)₂N, (C₉F₁₉)(CH₃)₂N, (C₁₀F₂₁)(CH₃)₂N, (C₁₁F₂₃)(CH₃)₂N, (C₁₂F₂₅)(CH₃)₂N, (C₁₃F₂₇)(CH₃)₂N, (C₁₄F₂₉)(CH₃)₂N, (C₁₅F₃₀(CH₃)₂N, (C₁₆F₃₃)(CH₃)₂N, (C₁₇F₃₅)(CH₃)₂N, (C₁₈F₃₇)(CH₃)₂N and the like. In addition, the protective film forming agent may exist in the form of a salt of the general formula [2]. It is possible to exemplify the salt by inorganic acid salts such as carbonate, hydrochloride, sulfate, nitrate and the like, and organic acid salts such as acetate, propionate, butyrate, phthalate and the like.

A compound represented by the general formula [3] is exemplified by: isocyanate compounds such as C₄H₉NCO, C₅H₁₁NCO, C₆H₁₃NCO, C₇H₁₅NCO, C₈H₁₇NCO, C₉H₁₉NCO, C₁₀H₂₁NCO, C₁₁H₂₃NCO, C₁₂H₂₅NCO, C₁₃H₂₇NCO, C₁₄H₂₉NCO, C₁₅H₃₁NCO, C₁₆H₃₃NCO, C₁₇H₃₅NCO, C₁₈H₃₇NCO, C₄F₉NCO, C₅F₁₁NCO, C₆F₁₃NCO, C₇F₁₅NCO, C₈F₁₇NCO, C₉F₁₉NCO, C₁₀F₂₁NCO, C₁₁F₂₃NCO, C₁₂F₂₅NCO, C₁₃F₂₇NCO, C₁₄F₂₉NCO, C₁₅F₃₁NCO, C₁₆F₃₃NCO, C₁₇F₃₅NCO, C₁₈F₃₇NCO, C₄F₇H₂NCO, C₅F₉H₂NCO, C₆F₁₁H₂NCO, C₇F₁₃H₂NCO, C₈F₁₅H₂NCO, C₉F₁₇H₂NCO, C₁₀F₁₉H₁₂NCO, C₁₁F₂₁H₁₂NCO, C₁₂F₂₃H₂NCO, C₁₃F₂₅H₂NCO, C₁₄F₂₇H₂NCO, C₁₅F₂₉H₂NCO, C₁₆F₃₁H₂NCO, C₁₇F₃₃H₂NCO, C₁₈F₃₅H₂NCO, C₄F₅H₄NCO, C₅F₇H₄NCO, C₆F₉H₄NCO, C₇F₁₁H₄NCO, C₈F₁₃H₄NCO, C₉F₁₅H₄NCO, C₁₀F₁₇H₄NCO, C₁₁F₁₉H₄NCO, C₁₂F₂₁H₄NCO, C₁₃F₂₃H₄NCO, C₁₄F₂₅H₄NCO, C₁₅F₂₇H₄NCO, C₁₆F₂₉H₄NCO, C₁₇F₃₁H₄NCO, C₁₈F₃₃H₄NCO, C₄H₈(NCO)₂, C₅H₁₀(NCO)₂, C₆H₁₂(NCO)₂, C₇H₁₄(NCO₂, C₈H₁₆(NCO)₂, C₉H₁₈(NCO)₂, C₁₀H₂₀(NCO)₂, C₁₁H₂₂(NCO)₂, C₁₂H₂₄(NCO)₂, C₁₃H₂₆(NCO)₂, C₁₄H₂₈(NCO)₂, C₁₅H₃₀(NCO)₂, C₁₆H₃₂(NCO)₂, C₁₇H₃₄(NCO)₂, C₁₈H₃₆(NCO)₂, (NCO)C₄H₈NCO, (NCO)C₅H₁₀NCO, (NCO)C₆H₁₂NCO, (NCO)C₇H₁₄NCO, (NCO)C₈H₁₆NCO, (NCO)C₉H₁₈NCO, (NCO)C₁₀H₂₀NCO, (NCO)C₁₁H₂₂NCO, (NCO)C₁₂H₂₄NCO, (NCO)C₁₃H₂₆NCO, (NCO)C₁₄H₂₈NCO, (NCO)C₁₅H₃₀NCO, (NCO)C₁₆H₃₂NCO, (NCO)C₁₇H₃₄NCO, (NCO)C₁₈H₃₆NCO, C₄H₇(NCO)₃, C₅H₉(NCO)₃, C₆H₁₁(NCO)₃, C₇H₁₃(NCO)₃, C₈H₁₅(NCO)₃, C₉H₁₇(NCO)₃, C₁₀H₁₉(NCO)₃, C₁₁H₂₁(NCO)₃, C₁₂H₂₃(NCO)₃, C₁₃H₂₅(NCO)₃, C₁₄H₂₇(NCO)₃, C₁₅H₂₉(NCO)₃, C₁₆H₃₁(NCO)₃, C₁₇H₃₃(NCO)₃, C₁₈H₃₅(NCO)₃, (NCO)₂C₄H₆(NCO)₂, (NCO)₂C₅H₈(NCO₂, (NCO)₂C₆H₁₀(NCO)₂, (NCO)₂C₇H₁₂(NCO)₂, (NCO)₂C₈H₁₄(NCO)₂, (NCO)₂C₉H₁₆(NCO)₂, (NCO)₂C₁₀H₁₈(NCO)₂, (NCO)₂C₁₁H₂₀(NCO)₂, (NCO)₂C₁₂H₂₂(NCO)₂, (NCO)₂C₁₃H₂₄(NCO)₂, (NCO)₂C₁₄H₂₆(NCO)₂, (NCO)₂C₁₅H₂₈(NCO)₂, (NCO)₂C₁₆H₃₀(NCO)₂, (NCO)₂C₁₇H₃₂(NCO)₂, (NCO)₂C₁₅H₃₄(NCO)₂ and the like: compounds obtained by substituting an isocyanate group (—NCO group) of the above isocyanate compounds with —SH group, —CONHOH group or a nitrogen element-containing cyclic structure such as an imidazoline ring (the following formula [5]); and the like.

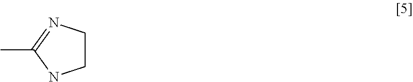

Examples of R¹ and R³ of the general formulas [1] and [2] are: alkyl group; phenyl group; phenyl group the hydrogen element of which is substituted with alkyl group; naphthyl group: these hydrocarbon groups whose hydrogen elements are partially or entirely substituted with a fluorine element(s); and the like. Additionally, examples of R⁵ of the general formula [3] are: aliphatic hydrocarbon: benzene: a benzene the hydrogen element of which is substituted with an alkyl group; naphthalene; these hydrocarbons the hydrogen elements of which are partially or entirely replaced with a fluorine element(s); and the like.

In the general formulas [1] to [3], if R¹ and R³ are C₆-C₁₈ monovalent hydrocarbon groups and R⁵ is a C₄-C₁₈ hydrocarbon, it becomes possible to impart a sufficient water repellency to the surface of the metal-based wafer, and additionally the sufficient water repellency on the surface can easily be maintained even after carrying out a rinsing treatment where a rinsing liquid consisting only of a protic polar solvent such as water and alcohol or a rinsing liquid containing the protic polar solvent as the principal component is retained on the surface on which the wafer-repellent protective film has already been formed. Moreover, it is preferable that R¹ and R³ have a carbon number of 8 to 18 or that R⁵ has a carbon number of 6 to 18 because the water repellency and the rinsing resistance are more excellently imparted thereby. The hydrocarbon group (or hydrocarbon) whose hydrogen elements may partially or entirely be replaced with a fluorine element(s) is preferably an alkyl group (an aliphatic saturated hydrocarbon), particularly preferably a straight-chained alkyl group (a straight-chained aliphatic saturated hydrocarbon). If the hydrocarbon group (or hydrocarbon) is a straight-chained alkyl group (a straight-chained aliphatic saturated hydrocarbon), hydrophobic moieties of the protective film forming agent tend to be arranged perpendicularly to the surface of the protective film at the time of forming the protective film so as to enhance the water repellency-imparting effect, which is therefore further preferable. In addition, it is preferable that R¹, R³ and R⁵ in the general formulas [1] to [3] are hydrocarbon groups (or hydrocarbon) whose hydrogen elements are partially or entirely replaced with a fluorine element(s), in order to obtain a greater water repellency.

The liquid chemical for forming protective film of the present invention can easily form an excellently water-repellent protective film on the surface of an article containing at least one kind of element selected from titanium, tungsten and ruthenium at its surface. Accordingly, it is preferable that the wafer is a wafer having at its surface an uneven pattern and containing at least one kind of element selected from titanium, tungsten and ruthenium at surfaces of recessed portions of the uneven pattern. In the case of a surface at which titanium element is contained, a compound represented by the general formula [1] or [2] or a compound represented by the general formula [3] where X is —CONHOH group exhibit a good compatibility, so it is preferable to use a liquid chemical for forming a protective film which liquid chemical contains these compounds. In the case of a surface at which tungsten element is contained, a compound represented by the general formula [1] or [2] or a compound represented by the general formula [3] where X is a cyclic structure containing a nitrogen element exhibit a good compatibility, so it is preferable to use a liquid chemical for forming a protective film which liquid chemical contains these compounds. In the case of a surface at which ruthenium element is contained, a compound represented by the general formula [1] or [2] or a compound represented by the general formula [3] where X is an isocyanate group or mercapto group or a cyclic structure containing a nitrogen element exhibit a good compatibility, so it is preferable to use a liquid chemical for forming a protective film which liquid chemical contains these compounds.

The concentration of the protective film forming agent in the liquid chemical for forming a protective film is preferably 0.0005 to 15 mass % relative to the total amount of 100 mass % of the liquid chemical. If the concentration is lower than 0.0005 mass %, the water repellency-imparting effect tends to be insufficient. Meanwhile, a higher concentration brings about a higher water repellency-imparting effect. However, if the concentration exceeds 15 mass %, the protective film forming agent tends to have difficulty in dissolving in a solvent, and sometimes requires a long period of operation time to substitute the liquid chemical for forming a protective film with a rinsing liquid so as to consume a large amount of rinsing liquid. Therefore, the concentration is more preferably 0.001 to 5 mass %, much more preferably 0.0015 to 3 mass %.

As a solvent usable for the liquid chemical for forming a protective film, it is preferable to use water, an organic solvent and a mixture liquid of water and an organic solvent. Preferably usable examples of the organic solvent are hydrocarbons, esters, ethers, ketones, halogen element-containing solvents, sulfoxide-based solvents, lactone-based solvents, carbonate-based solvents, alcohols, polyalcohol derivatives having OH group, polyalcohol derivatives having no OH group, nitrogen element-containing solvents and a mixture solution of these.

Concrete examples of the organic solvent are the same organic solvents usable for the cleaning liquid A.

Additionally, it is preferable to use a nonflammable solvent as a part or the entire of the solvent since the liquid chemical for forming a protective film becomes nonflammable or increases in flash point thereby reducing the risk of the liquid chemical. Most of the halogen element-containing solvents are nonflammable, and such a halogen element-containing nonflammable solvent can preferably be used as a nonflammable solvent. It is also possible to use water as the nonflammable solvent

Additionally, it is preferable, in view of safety under the fire protection law, to use a solvent having a flash point exceeding 70° C. as the solvent.

According to “Globally Harmonized System of Classification and Labelling of Chemicals; GHS”, a solvent having a flash point of not higher than 93° C. is defined as “a flammable liquid”. Therefore, when a solvent having a flash point exceeding 93° C. is used as the solvent, the liquid chemical for forming a protective film tends to have a flash point exceeding 93° C. even if the solvent is not nonflammable one. Hence the liquid chemical hardly corresponds to “a flammable liquid” and therefore further preferable in view of safety.

Most of the lactone-based solvents, the carbonate-based solvents, alcohols having a large molecular weight or two or more OH groups and the polyalcohol derivatives have high flash point so as to be preferably used as the solvent because the risk of the liquid chemical for forming a protective film can be lowered. From the viewpoint of safety, a solvent having a flash point exceeding 70° C. is more preferably used as the solvent, which is concretely exemplified by γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone, propylene carbonate, heptanol, octanol, ethylene glycol, diethylene glycol, 1,2-propanediol, 1,3-propanediol, dipropylene glycol, 1,2-butanediol, 1,3-butanediol, 1,4-butanediol, triethylene glycol, tripropylene glycol, tetraethylene glycol, tetrapropylene glycol, glycerine, diethylene glycol monomethyl ether, diethylene glycol monoethyl ether, diethylene glycol monopropyl ether, diethylene glycol monobutyl ether, triethylene glycol monomethyl ether, triethylene glycol monoethyl ether, triethylene glycol monopropyl ether, triethylene glycol monobutyl ether, tetraethylene glycol monomethyl ether, tetraethylene glycol monoethyl ether, tetraethylene glycol monopropyl ether, tetraethylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tripropylene glycol monoethyl ether, tripropylene glycol monopropyl ether, tripropylene glycol monobutyl ether, tetrapropylene glycol monomethyl ether, ethylene glycol dibutyl ether, ethylene glycol monobutyl ether acetate, ethylene glycol diacetate, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol diacetate, dipropylene glycol methyl propyl ether, dipropylene glycol monomethyl ether acetate, dipropylene glycol monoethyl ether acetate, dipropylene glycol monobutyl ether acetate, dipropylene glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol diacetate, glycerine triacetate and the like. Furthermore, a solvent having a flash point exceeding 93° C. is much more preferably used as the solvent, which is concretely exemplified by γ-butyrolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone, propylene carbonate, ethylene glycol, diethylene glycol, 1,2-propanediol, 1,3-propanediol, dipropylene glycol, 1,2-butanediol, 1,3-butanediol, 1,4-butanediol, triethylene glycol, tripropylene glycol, tetraethylene glycol, tetrapropylene glycol, glycerine, diethylene glycol monomethyl ether, diethylene glycol monopropyl ether, diethylene glycol monobutyl ether, triethylene glycol monomethyl ether, triethylene glycol monoethyl ether, triethylene glycol monopropyl ether, triethylene glycol monobutyl ether, tetraethylene glycol monomethyl ether, tetraethylene glycol monoethyl ether, tetraethylene glycol monopropyl ether, tetraethylene glycol monobutyl ether, dipropylene glycol monopropyl ether, dipropylene glycol monobutyl ether, tripropylene glycol monomethyl ether, tripropylene glycol monoethyl ether, tripropylene glycol monopropyl ether, tripropylene glycol monobutyl ether, tetrapropylene glycol monomethyl ether, ethylene glycol diacetate, diethylene glycol butyl methyl ether, diethylene glycol dibutyl ether, diethylene glycol diacetate, diethylene glycol monomethyl ether acetate, diethylene glycol monoethyl ether acetate, diethylene glycol monobutyl ether acetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol diacetate, dipropylene glycol diacetate, dipropylene glycol monomethyl ether acetate, dipropylene glycol monoethyl ether acetate, dipropylene glycol monobutyl ether acetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol diacetate, glycerine triacetate and the like.

Moreover, from the reason that far excellent water repellency can be obtained, it is preferable that the solvent is selected from hydrocarbons, esters, ethers, ketones, lactone-based solvents, carbonate-based solvents, polyalcohol derivatives having no OH group, water and a mixture liquid of these. In consideration of the substitutability with a cleaning liquid (a water-based cleaning liquid in particular), it is preferable that the solvent is selected from polyalcohol derivatives having no OH group, water and a mixture liquid of these. In order to dissolve a larger amount of the protective film forming agent, the solvent may contain an alcohol.

In order to accelerate the formation of the protective film from the protective film forming agent, a catalyst may be added to the liquid chemical for forming a protective film The amount of the catalyst to be added is preferably 0.01 to 50 mass % relative to the total amount of 100 mass % of the protective film forming agent.

When increasing the temperature of the liquid chemical for forming a protective film, it becomes possible to easily form the protective film in a shorter time. A temperature at which a uniform protective film can readily be formed is not lower than 10° C. and lower than the boiling point of the liquid chemical. Particularly, it is preferable to keep a temperature of not lower than 15° C. and not higher than a temperature 10° C. lower than the boiling point of the liquid chemical. A temperature of not lower than 35° C. and not higher than a temperature 10° C. lower than the boiling point of the liquid chemical is more preferable because water repellency and rinsing resistance are more greatly exhibited. Further, a temperature of not lower than 55° C. and not higher than a temperature 10° C. lower than the boiling point of the liquid chemical is much more preferable because water repellency and rinsing resistance are much more greatly exhibited. It is preferable that the temperature of the liquid chemical is kept at the above-mentioned temperature while the liquid chemical is retained at least in the recessed portions of the uneven pattern. Incidentally, the boiling point of the liquid chemical refers to the boiling point of a component having the largest amount by mass among components contained in the liquid chemical for forming a protective film

After the protective film forming step, the liquid chemical retained at least in the recessed portions of the uneven pattern is substituted with a rinsing liquid (hereinafter, this step is sometimes referred to as “a rinsing treatment step”), and then it may be brought into a drying step. The rinsing liquid contains a protic polar solvent, and it may consist only of a protic polar solvent or may be a mixture liquid containing a protic polar solvent as the principal component while containing an aprotic polar solvent or a nonpolar solvent as another component. Examples of protic polar solvent are water, alcohols and the like. Concrete examples of alcohols are the same as cited for the cleaning liquid A. Moreover, “a rinsing liquid containing a protic polar solvent as the principal component” means a rinsing liquid containing 50 mass % or more protic polar solvent while containing an aprotic polar solvent or a nonpolar solvent as another solvent component. Examples of the aprotic polar solvent are ketones, sulfoxide-based solvents, lactone-based solvents, carbonate-based solvents, polyalcohol derivatives having no OH group and nitrogen element-containing solvents. Examples of the nonpolar solvent include hydrocarbons, esters, ethers, halogen element-containing solvents. Examples of the solvent are the same organic solvent as usable for the cleaning liquid A or for the liquid chemical for forming a protective film

Additionally, it is also possible to use as the rinsing liquid: a liquid obtained by mixing at least one kind of acid, alkali and a surfactant into the above-mentioned solvent: a liquid in which the protective film forming agent used for the liquid chemical for forming a protective film is contained in the above-mentioned solvent at a concentration lower than that of the liquid chemical: and the like. From the viewpoint of removing particles and metal impurities, it is more preferable that the rinsing liquid is water, an alcohol or a mixture liquid containing these as the principal component.

If an alcohol is used as the protic polar solvent for the rinsing liquid, water repellency becomes difficult to reduce after the rinsing treatment step, which is therefore preferable. Furthermore, a mixture liquid containing an alcohol (that serves as a protic polar solvent) as the principal component while containing an aprotic polar solvent or a nonpolar solvent as another component is used as the rinsing liquid, water repellency becomes more difficult to reduce after the rinsing treatment step, which is therefore more preferable. Among alcohols, isopropyl alcohol is particularly preferable because it is generally used in cleaning of wafers and reasonable in cost.

In the rinsing treatment step, substitution with the rinsing liquid may be conducted twice or more. More specifically, the liquid chemical for forming a protective film may be substituted with a first kind of rinsing liquid and then the first kind of rinsing liquid may be substituted successively with two or more kinds of rinsing liquids different from the above-mentioned first kind of rinsing liquid, followed by the drying step. In the case where the rinsing treatment is performed twice or more, it is important that a rinsing treatment using a rinsing liquid consisting only of a protic polar solvent or a rinsing liquid containing a protic polar solvent as the principal component is carried out at least once, and it is possible in the other times to use other rinsing liquid than the rinsing liquid consisting only of a protic polar solvent or the rinsing liquid containing a protic polar solvent as the principal component.

FIG. 4 is a schematic view showing a condition in which a rinsing liquid is retained in recessed portions 4 that had been provided with water repellency by the liquid chemical for forming a protective film The wafer of the schematic view of FIG. 4 shows a part of the a-a′ cross section in FIG. 1. On the surface of the uneven pattern, a protective film 10 is formed by the liquid chemical, so that water repellency is imparted thereto. The protective film 10 is held on the wafer surface even after a rinsing liquid 9 is removed from the uneven pattern.

When the protective film 10 is formed at least on the surfaces of the recessed portions of the uneven pattern of the wafer by the liquid chemical for forming a protective film, the contact angle on the assumption that water is retained on the surfaces is preferably 50 to 130°, because pattern collapse becomes difficult to occur. The contact angle is more preferably 60 to 120°, much more preferably 65 to 115°, and particularly preferably 70 to 110° because a contact angle closer to 90° makes capillary force (that acts on the recessed portions) smaller so as to get pattern collapse more difficult to occur. Furthermore, it is ideal to put the capillary force close to 0.0 MN/m² as much as possible by adjusting the contact angle to the liquid to around 90°. If the contact angle of the surfaces of the recessed portions after the rinsing treatment step is kept within the above-mentioned range, water repellency is maintained so sufficiently as to well reduce pattern collapse, and therefore it is considered possible to obtain an excellent rinsing resistance.

Then, as discussed in the rinsing liquid removal step, there is conducted a step of removing a rinsing liquid from the uneven pattern by drying, the liquid having been retained in the recessed portions 4 on which the protective film is formed by the liquid chemical. At this time, the rinsing liquid retained in the recessed portions may be the rinsing liquid used in the rinsing treatment step. In view of the cleanliness of the wafer, the rinsing liquid is preferably water, an alcohol, or a mixture liquid containing either as the principal component. Moreover, an alcohol or a mixture liquid containing an alcohol as the principal component is further preferable. Additionally, it is also possible to get the rinsing liquid retained on the unevenly patterned surface after once removing the rinsing liquid from the unevenly patterned surface, followed by drying.

A time for the rinsing treatment step, i.e. a time to retain the rinsing liquid is preferably not shorter than 10 seconds, more preferably not shorter than 20 seconds from the viewpoint of removing particles and impurities from the unevenly patterned surface. If an alcohol or a mixture liquid containing an alcohol as the principal component is used as the rinsing liquid, the water repellency of the wafer surface tends to be difficult to decrease even after conducting the rinsing treatment step, in view of the effect of maintaining a water repellent performance of the protective film formed on the unevenly patterned surface. On the other hand, if the time for the rinsing treatment step is too long, the productivity is so lowered. Hence the time for the rinsing treatment step is preferably within 15 minutes.

In the rinsing liquid removal step, the rinsing liquid retained on the uneven pattern is removed by drying. The drying is conducted preferably by a conventionally known drying method such as spin drying, IPA (2-propanol) steam drying, Marangoni drying, heating drying, blowing drying, warm air drying, vacuum drying and the like.

Then, as discussed in the water-repellent protective film removal step, there is performed a step of removing the protective film 10. In the case of removing the water-repellent protective film, it is effective to cleave C—C bond and C—F bond in the water-repellent protective film A method therefor is not particularly limited so long as it is possible to cleave the above-mentioned bonds but exemplified by: irradiating the wafer surface with light; heating the wafer; exposing the wafer to ozone; irradiating the wafer surface with plasma; subjecting the wafer surface to corona discharge; and the like.

In the case of removing the protective film 10 by light irradiation, it is preferable to conduct an irradiation with ultraviolet rays having a wavelength of shorter than 340 nm and 240 nm (corresponding to bond energies of C—C bond and C—F bond in the protective film 10, i.e., 83 kcal/mol and 116 kcal/mol, respectively). As the light source therefor, there is used a metal halide lamp, a low-pressure mercury lamp, a high-pressure mercury lamp, an excimer lamp, a carbon arc or the like. In the case of the metal halide lamp, the intensity of the ultraviolet irradiation is preferably not less than 100 mW/cm², particularly preferably not less than 200 mW/cm², as a measurement value obtained by the illuminance meter (Intensity meter UM-10 produced by Konica Minolta Sensing, Inc., Light-Receptor UM-360 [Peak sensitivity wavelength: 365 nm, Measured wavelength range: 310 to 400 nm]). Incidentally, an irradiation intensity of less than 100 mW/cm² takes a long time to remove the protective film 10. Additionally, in the case of the low-pressure mercury lamp, the ultraviolet irradiation is to be performed with shorter wavelengths so that removal of the protective film 10 is achieved in a short time even if the intensity is low, which is therefore preferable.

Additionally, in the case of removing the protective film 10 by light irradiation, it is particularly preferable to generate ozone while decomposing the components of the protective film 10 by ultraviolet rays and then to induce oxidation-volatilization of the components of the protective film 10 by the ozone, since a treatment time is saved thereby. As the light source therefor, the low-pressure mercury lamp, the excimer lamp or the like is used. Moreover, the wafer may be heated while being subjected to light irradiation.

In the case of heating the wafer, heating of the wafer is conducted at 400 to 1000° C., preferably at 500 to 900° C. The heating time is preferably kept from 10 seconds to 60 minutes, more preferably from 30 seconds to 10 minutes. Additionally, this step may be conducted in combination with ozone exposure, plasma irradiation, corona discharge or the like. Furthermore, the light irradiation may be conducted while heating the wafer.

As the method for removing the protective film 10 by heating, there are a method of bringing a wafer into contact with a heat source, a method of bringing a wafer into a heated atmosphere such as a heat treatment furnace, and the like. The method of bringing a wafer into a heated atmosphere can easily and uniformly provide the wafer surface with energy for removing the protective film 10 even in a case of conducting a treatment on two or more wafers. This method is operationally convenient, achieves the treatment within a short period of time and excellent in treatment ability. Therefore, this is an industrially advantageous method.

In the case of exposing the wafer to ozone, it is preferable to expose the wafer surface to ozone generated by ultraviolet irradiation using the low-pressure mercury lamp, low-temperature discharge using high voltages or the like. The wafer may be irradiated with light or heated while being exposed to ozone.

In the film removal step, the protective film formed on the wafer surface can efficiently be removed by combining the above-mentioned light irradiation, heating, ozone exposure, plasma irradiation, and corona discharge.

### EXAMPLES

A technique of making a wafer surface into a surface having an uneven pattern and a technique of substituting a cleaning liquid retained at least in recessed portions of the uneven pattern with other cleaning liquid have been variously studied as discussed in other literatures and the like, and therefore such techniques have already been established. Accordingly, in the present invention, evaluations of a liquid chemical for forming a protective film were mainly performed. It is apparent from the following equation that pattern collapse greatly depends on the contact angle of a cleaning liquid to the wafer surface, i.e. on the contact angle of a liquid drop and on the surface tension of the cleaning liquid.

P=2×γ×cosθ/S

(In the equation, γ represents the surface tension of liquid retained in the recessed portions, θ represents the contact angle of the liquid retained in the recessed portions to the surfaces of the recessed portions, and S represents the width of the recessed portions.)

In a case of a cleaning liquid retained in recessed portions 4 of an uneven pattern 2, the contact angle of a liquid drop and the capillary force acting on the recessed portions (which force is regarded as being equal to pattern collapse) are in correlation with each other, so that it is also possible to derive the capillary force from the equation and the evaluations made on the contact angle of the liquid drop to a protective film 10.

However, in the case of a wafer having an unevenly patterned surface, it is not possible to exactly evaluate the contact angle of the protective film 10 itself, the protective film 10 being formed on the unevenly patterned surface.

An evaluation of the contact angle of waterdrop is conducted by dropping several microliters of waterdrop on a surface of a sample (a substrate) and then by measuring an angle formed between the waterdrop and the substrate surface, as discussed in JIS R 3257 (Testing method of wettability of glass substrate surface). However, in the case of the wafer having a pattern, the contact angle is enormously large. This is because Wenzel's effect or Cassie's effect is caused so that an apparent contact angle of the waterdrop is increased under the influence of a surface shape (roughness) of the substrate upon the contact angle.

In view of the above, in Examples of the present invention, various kinds of evaluations were carried out in such a manner as to supply the liquid chemical onto a wafer having a smooth surface to form a protective film on the wafer surface. The protective film was referred to as a protective film 10 formed on a surface of a wafer 1 having at its surface an uneven pattern 2. In Examples of the present invention, there were used “a wafer having a titanium nitride film” (indicated by “TiN” in Table) obtained by forming a titanium nitride layer on a silicon wafer having a smooth surface, “a wafer having a tungsten film” (indicated by “W” in Table) obtained by forming a tungsten layer on a silicon wafer having a smooth surface, and “a wafer having a ruthenium film” (indicated by “Ru” in Table) obtained by forming a ruthenium layer on a silicon wafer having a smooth surface.

Details will be discussed below. Hereinafter, there will be discussed: a method for evaluating a wafer to which a liquid chemical for forming a protective film is supplied: preparation of the liquid chemical for forming a protective film: and results of evaluation made after supplying the liquid chemical for forming a protective film to the wafer.

[Method for Evaluating Wafer to which Liquid Chemical for forming Protective Film is supplied]

As a method for evaluating a wafer to which a liquid chemical for forming a protective film is supplied, the following evaluations (1) to (3) were performed.

(1) Evaluation of Contact Angle of Protective Film formed on Wafer Surface

About 2 ᵢd of pure water was dropped on a surface of a wafer on which a protective film was formed, followed by measuring an angle (contact angle) formed between the waterdrop and the wafer surface by using a contact angle meter (produced by Kyowa Interface Science Co., Ltd.: CA-X Model). In this evaluation, a protective film confirmed to have a contact angle within a range of from 50 to 130° was classified as an acceptable one.

(2) Removability of Protective Film

Under the following conditions, a sample was irradiated with UV rays from a metal halide lamp for 2 hours, upon which an evaluation of removability of the protective film at the film removal step was made. A sample on which waterdrop had a contact angle of not larger than 30° after the irradiation was classified as acceptable one.
Lamp: M015-L312 produced by EYE GRAPHICS CO., LTD. (Intensity: 1.5 kW)
Illuminance: 128 mW/cm² as a measurement value obtained under the following conditions
Measuring Apparatus: Ultraviolet Intensity Meter (UM-10 produced by Konica Minolta Sensing, Inc.)
Light-Receptor: UM-360 (Light-Receptive Wavelength: 310-400 nm, Peak Wavelength: 365 nm)
Measuring Mode: Irradiance Measurement

(3) Evaluation of Surface Smoothness of Wafer after removing Protective Film

The surface was observed by atomic force microscope (produced by Seiko Instruments Inc.: SPI3700, 2.5 micrometer square scan). Then, there was obtained a difference ΔRa (nm) in the centerline average surface roughness Ra (nm) of the surface of the wafer between before and after the cleaning. Incidentally, Ra is a three-dimensionally enlarged one obtained by applying the centerline average roughness defined by JIS B 0601 to a measured surface and is calculated as “an average value of absolute values of deviation from standard surface to designated surface” from the following equation.

$$Ra = \frac{1}{{s}_{0}} {\int }_{{Y}_{T}}^{{Y}_{B}} {\int }_{{X}_{L}}^{{X}_{R}} \vert F ( X , Y ) - {Z}_{0} \vert d X d Y$$

where X_{L} and X_{R}, and Y_{B} and Y_{T} represent a measuring range in the X coordinate and the Y coordinate, respectively. S₀ represents an area on the assumption that the measured surface is ideally flat, and is a value obtained by (X_{R}−X_{L})×(Y_{B}−Y_{T}). Additionally, F(X,Y) represents the height at a measured point (X,Y). Z₀ represents the average height within the measured surface.

The Ra value of the wafer surface before the protective film was formed thereon and the Ra value of the wafer surface after the protective film was removed therefrom were measured. If a difference between them (ΔRa) was within ±1 nm, the wafer surface was regarded as not being eroded by the cleaning and not leaving residues of the protective film thereon, and therefore classified as an acceptable one.

### Example 1

(I-1) Preparation of Liquid Chemical for forming Water-Repellent Protective Film

A mixture of: 0.01 g of perfluorohexylethylphosphonic acid [C₆F₁₃—C₂H₄—P(O)(OH)₂] that served as a water-repellent protective film forming agent: and 99.99 g of propylene glycol monomethyl ether acetate that served as a solvent (hereinafter, referred to as “PGMEA”) was stirred at 20° C. for 2 hours, thereby obtaining a liquid chemical for forming a protective film which liquid chemical had a concentration of the protective film forming agent (hereinafter referred to as “a protective film forming agent concentration”) of 0.01 mass % relative to the total amount of the liquid chemical for forming a protective film

(I-2) Wafer Cleaning Step (Pretreatment Step)

As a pretreatment step 2, a wafer having a smooth titanium nitride film (a silicon wafer formed having on its surface a titanium nitride layer of 50 nm thickness) was immersed in 1 mass % hydrogen peroxide solution for 1 minute at room temperature, and then immersed in pure water for 1 minute. Furthermore, as a pretreatment step 3, the wafer was immersed in isopropyl alcohol (hereinafter referred to as “iPA”) for 1 minute.

(I-3) From Step of Forming Water-Repellent Protective Film on Wafer to Rinsing Liquid Removal Step

In a protective film forming step, the wafer having a titanium nitride film was immersed in the liquid chemical for forming a protective film which liquid chemical had been prepared according to the “(I-1) Preparation of Liquid Chemical for forming Water-Repellent Protective Film” section, for 10 minutes at 20° C., thereby causing adsorption of a protective film forming agent to form a protective film on the wafer surface. Thereafter, a rinsing treatment step was conducted in such a manner as to immerse the wafer having a titanium nitride film in iPA for 5 seconds, 30 seconds or 60 seconds (indicated in Tables by “Rinsing Time [5 sec]”, “Rinsing Time [30 sec]” and “Rinsing Time [60 sec]”). In a rinsing liquid removal step, the wafer having a titanium nitride film was taken out of iPA, followed by blowing air to remove the iPA from the surface.

As a result of evaluating the thus obtained wafer having a titanium nitride film in a manner discussed in the above [Method for Evaluating Wafer to which Liquid Chemical for forming Protective Film is supplied] section, a wafer having an initial contact angle of smaller than 10° before the protective film formation was confirmed to have a contact angle of 108° in the case where the rinsing time after the protective film formation was 5 seconds, as shown in Table 1, from which it was confirmed that the water repellency-imparting effect was excellently obtained. Likewise, a wafer in the case where the rinsing time after the protective film formation was 30 seconds had a contact angle of 105° and a wafer in the case where the rinsing time after the protective film formation was 60 seconds had a contact angle of 104°, from which it was confirmed that the water repellency was favorably maintained even after the rinsing treatment. In all cases, the contact angle after UV irradiation was smaller than 10°, which means that removal of the protective film was achieved. Furthermore, in all cases the ΔRa value of the wafer after UV irradiation was within ±0.5 nm, with which it was confirmed that the wafer was not eroded at the time of rinsing and that residues of the protective film did not remain after UV irradiation. Also concerning all examples other than the present Example 1, it was confirmed that removal of the protective film was achieved because the contact angle after UV irradiation was smaller than 10°, and additionally it was confirmed that the wafer was not eroded at the time of rinsing and residues of the protective film did not remain after UV irradiation because the ΔRa value of the wafer after UV irradiation was within ±0.5 nm. Meanwhile, in all of Comparative Examples, the water repellency-imparting effect and the rinsing resistance were obtained insufficiently as will be discussed below; therefore, evaluations on removability of the protective film and on surface smoothness of the wafer after removing the protective film were omitted.

TABLE 1

| | | | | | Temperature of | | | | | |
|---|---|---|---|---|---|---|---|---|---|---|
| | Liquid Chemical for Forming Protective Film | | | | Liquid Chemical | | Contact Angle [°] | | | |
| | | Protective | | | During Water- | | Before | After Protective Film | | |
| | | Film Form- | | | Repellent | Rins- | Protec- | is formed | | |
| | | ing Agent | | | Protective | ing | tive | Rinsing | Rinsing | Rinsing |
| | Protective Film | Concentration | | Wa- | Film Forming | Liq- | Film is | Time | Time | Time |
| | Forming Agent | [mass %] | Solvent | fer | Step [° C.] | uid | formed | [5 sec] | [30 sec] | [60 sec] |
| Example 1 | C₆F₁₃—C₂H₄—P(O)(OH)₂ | 0.01 | PGMEA | TiN | 20 | iPA | <10 | 108 | 105 | 104 |
| Example 2 | C₆F₁₃—C₂H₄—P(O)(OH)₂ | 0.01 | PGMEA/iPA-0.1 | TiN | 20 | iPA | <10 | 108 | 104 | 104 |
| Example 3 | C₆F₁₃—C₂H₄—P(O)(OH)₂ | 0.01 | DGEEA | TiN | 20 | iPA | <10 | 108 | 104 | 104 |
| Example 4 | C₆F₁₃—C₂H₄—P(O)(OH)₂ | 0.01 | DGEEA/iPA-0.1 | TiN | 20 | iPA | <10 | 108 | 105 | 104 |
| Example 5 | C₆F₁₃—C₂H₄—P(O)(OH)₂ | 0.01 | Water/iPA-30 | TiN | 20 | iPA | <10 | 110 | 109 | 108 |
| Example 6 | C₆F₁₃—C₂H₄—P(O)(OH)₂ | 0.0008 | PGMEA | TiN | 20 | iPA | <10 | 105 | 103 | 102 |
| Example 7 | C₆F₁₃—C₂H₄—P(O)(OH)₂ | 0.0012 | PGMEA | TiN | 20 | iPA | <10 | 105 | 103 | 102 |
| Example 8 | C₆F₁₃—C₂H₄—P(O)(OH)₂ | 0.003 | PGMEA | TiN | 20 | iPA | <10 | 107 | 105 | 104 |
| Example 9 | C₆F₁₃—C₂H₄—P(O)(OH)₂ | 0.005 | PGMEA | TiN | 20 | iPA | <10 | 108 | 106 | 106 |
| Example 10 | C₆F₁₃—C₂H₄—P(O)(OH)₂ | 0.03 | PGMEA | TiN | 20 | iPA | <10 | 110 | 109 | 109 |
| Example 11 | C₆F₁₃—C₂H₄—P(O)(OH)₂ | 0.05 | Water/iPA-30 | TiN | 20 | iPA | <10 | 111 | 110 | 110 |
| Example 12 | C₆F₁₃—C₂H₄—P(O)(OH)₂ | 0.1 | Water/iPA-30 | TiN | 20 | iPA | <10 | 111 | 111 | 110 |
| Example 13 | C₆F₁₃—C₂H₄—P(O)(OH)₂ | 0.5 | Water/iPA-30 | TiN | 20 | iPA | <10 | 112 | 112 | 112 |
| Example 14 | C₆F₁₃—C₂H₄—P(O)(OH)₂ | 1 | Water/iPA-30 | TiN | 20 | iPA | <10 | 112 | 112 | 112 |
| Example 15 | C₆F₁₃—C₂H₄—P(O)(OH)₂ | 5 | Water/iPA-30 | TiN | 20 | iPA | <10 | 113 | 113 | 113 |
| Example 16 | C₆F₁₃—C₂H₄—P(O)(OH)₂ | 10 | Water/iPA-30 | TiN | 20 | iPA | <10 | 113 | 113 | 113 |
| Example 17 | C₆F₁₃—C₂H₄—P(O)(OH)₂ | 0.01 | PGMEA | TiN | 40 | iPA | <10 | 111 | 111 | 110 |
| Example 18 | C₆F₁₃—C₂H₄—P(O)(OH)₂ | 0.01 | PGMEA | TiN | 60 | iPA | <10 | 113 | 113 | 113 |
| Example 19 | C₆F₁₃—C₂H₄—P(O)(OH)₂ | 0.01 | Water/iPA-30 | TiN | 60 | iPA | <10 | 113 | 112 | 112 |
| Example 20 | C₆F₁₃—C₂H₄—P(O)(OH)₂ | 0.1 | Water/iPA-30 | TiN | 60 | iPA | <10 | 114 | 114 | 113 |
| Example 21 | C₆F₁₃—C₂H₄—P(O)(OH)₂ | 0.5 | Water/iPA-30 | TiN | 60 | iPA | <10 | 115 | 114 | 114 |
| Example 22 | C₄F₉—C₂H₄—P(O)(OH)₂ | 0.01 | DGEEA/iPA-0.1 | TiN | 20 | iPA | <10 | 104 | 103 | 103 |
| Example 23 | C₁₂H₂₅P(O)(OH)₂ | 0.003 | PGMEA | TiN | 60 | iPA | <10 | 100 | 100 | 100 |
| Example 24 | C₁₀H₂₁P(O)(OH)₂ | 0.005 | PGMEA | TiN | 60 | iPA | <10 | 98 | 97 | 97 |
| Example 25 | C₈H₁₇P(O)(OH)₂ | 0.1 | PGMEA | TiN | 60 | iPA | <10 | 93 | 91 | 91 |
| Example 26 | C₆H₁₃P(O)(OH)₂ | 0.1 | PGMEA | TiN | 60 | iPA | <10 | 88 | 86 | 86 |
| Example 27 | C₁₀H₂₁P(O)(OC₂H₅)₂ | 0.1 | PGMEA | TiN | 60 | iPA | <10 | 55 | 52 | 51 |
| Example 28 | C₈F₁₇—C₂H₄—NH₂ | 0.1 | iPA | TiN | 20 | iPA | <10 | 92 | 91 | 91 |
| Example 29 | C₆F₁₃—C₂H₄—NH₂ | 0.1 | iPA | TiN | 20 | iPA | <10 | 83 | 63 | 55 |
| Example 30 | C₆F₁₃—C₂H₄—NH₂ | 1 | iPA | TiN | 20 | iPA | <10 | 85 | 62 | 57 |
| Example 31 | C₆F₁₃—C₂H₄—NH₂ | 5 | iPA | TiN | 20 | iPA | <10 | 88 | 71 | 61 |
| Example 32 | C₆F₁₃—C₂H₄—NH₂ | 0.1 | iPA | TiN | 60 | iPA | <10 | 85 | 73 | 66 |
| Example 33 | C₆F₁₃—C₂H₄—NH₂ | 5 | iPA | TiN | 60 | iPA | <10 | 88 | 76 | 67 |
| Example 34 | C₆F₁₃—C₂H₄—NH₂ | 10 | iPA | TiN | 60 | iPA | <10 | 89 | 79 | 78 |
| Example 35 | C₈H₁₇NH₂ | 1 | iPA | TiN | 20 | iPA | <10 | 80 | 66 | 58 |
| Example 36 | C₈H₁₇NHC₈H₁₇ | 1 | iPA | TiN | 20 | iPA | <10 | 76 | 59 | 51 |
| Example 37 | C₇H₁₅CONHOH | 0.1 | Water | TiN | 20 | iPA | <10 | 94 | 92 | 92 |
| Example 38 | C₇H₁₅CONHOH | 0.1 | Water | TiN | 60 | iPA | <10 | 100 | 98 | 97 |

### Examples 2 to 54

Upon modifying the conditions employed in Example 1 (as to the protective film forming agent, the solvent for the liquid chemical for forming a protective film, the protective film forming agent concentration, the temperature of the liquid chemical during the water-repellent protective film forming step, and the rinsing liquid), a surface treatment was conducted on each wafer in the same manner as in Example 1, followed by evaluation of these. The results are shown in Tables 1 and 2.

TABLE 2

| | | | | | Temperature of | | | | | |
|---|---|---|---|---|---|---|---|---|---|---|
| | Liquid Chemical for Forming Protective Film | | | | Liquid Chemical | | Contact Angle [°] | | | |
| | | Protective | | | During Water- | | Before | After Protective Film | | |
| | | Film Form- | | | Repellent | Rins- | Protec- | is formed | | |
| | | ing Agent | | | Protective | ing | tive | Rinsing | Rinsing | Rinsing |
| | Protective Film | Concentration | | Wa- | Film Forming | Liq- | Film is | Time | Time | Time |
| | Forming Agent | [mass %] | Solvent | fer | Step [° C.] | uid | formed | [5 sec] | [30 sec] | [60 sec] |
| Example 39 | C₆F₁₃—C₂H₄—P(O)(OH)₂ | 0.01 | PGMEA | TiN | 20 | Water | <10 | 108 | 85 | 80 |
| Example 40 | C₆F₁₃—C₂H₄—P(O)(OH)₂ | 0.01 | DGEEA | TiN | 20 | Water | <10 | 108 | 96 | 92 |
| Example 41 | C₆F₁₃—C₂H₄—P(O)(OH)₂ | 0.01 | DGEEA/ | TiN | 20 | Water | <10 | 108 | 97 | 92 |
| | | | iPA-0.1 | | | | | | | |
| Example 42 | C₆F₁₃—C₂H₄—P(O)(OH)₂ | 0.01 | Water/iPA-30 | TiN | 20 | Water | <10 | 110 | 105 | 98 |
| Example 43 | C₆F₁₃—C₂H₄—P(O)(OH)₂ | 0.1 | Water/iPA-30 | TiN | 20 | Water | <10 | 111 | 108 | 100 |
| Example 44 | C₆F₁₃—C₂H₄—P(O)(OH)₂ | 0.5 | Water/iPA-30 | TiN | 20 | Water | <10 | 112 | 108 | 101 |
| Example 45 | C₆F₁₃—C₂H₄—P(O)(OH)₂ | 0.01 | PGMEA | TiN | 60 | Water | <10 | 113 | 105 | 98 |
| Example 46 | C₆F₁₃—C₂H₄—P(O)(OH)₂ | 0.01 | Water/iPA-30 | TiN | 60 | Water | <10 | 113 | 108 | 105 |
| Example 47 | C₆F₁₃—C₂H₄—P(O)(OH)₂ | 0.1 | Water/iPA-30 | TiN | 60 | Water | <10 | 114 | 110 | 107 |
| Example 48 | C₆F₁₃—C₂H₄—P(O)(OH)₂ | 0.5 | Water/iPA-30 | TiN | 60 | Water | <10 | 115 | 110 | 108 |
| Example 49 | C₄F₉—C₂H₄—P(O)(OH)₂ | 0.01 | DGEEA/ | TiN | 20 | Water | <10 | 104 | 60 | 51 |
| | | | iPA-0.1 | | | | | | | |
| Example 50 | C₁₂H₂₅P(O)(OH)₂ | 0.003 | PGMEA | TiN | 60 | Water | <10 | 100 | 85 | 73 |
| Example 51 | C₁₀H₂₁P(O)(OH)₂ | 0.005 | PGMEA | TiN | 60 | Water | <10 | 98 | 80 | 70 |
| Example 52 | C₈H₁₇P(O)(OH)₂ | 0.1 | PGMEA | TiN | 60 | Water | <10 | 93 | 70 | 55 |
| Example 53 | C₆H₁₃P(O)(OH)₂ | 0.1 | PGMEA | TiN | 60 | Water | <10 | 88 | 64 | 51 |
| Example 54 | C₇H₁₅CONHOH | 0.1 | Water | TiN | 20 | Water | <10 | 94 | 87 | 79 |
| Comparative | C₄H₉P(O)(OH)₂ | 0.007 | Water/iPA-30 | TiN | 20 | iPA | <10 | 50 | 48 | 47 |
| Example 1 | | | | | | | | | | |
| Comparative | C₄H₉NH₂ | 10 | iPA | TiN | 60 | iPA | <10 | 58 | 43 | 36 |
| Example 2 | | | | | | | | | | |
| Comparative | CH₃CONHOH | 0.1 | Water | TiN | 20 | iPA | <10 | 33 | 28 | 24 |
| Example 3 | | | | | | | | | | |
| Comparative | C₄H₉P(O)(OH)₂ | 0.1 | Water/iPA-30 | TiN | 20 | Water | <10 | 65 | 30 | 25 |
| Example 4 | | | | | | | | | | |
| Comparative | CH₃CONHOH | 0.1 | Water | TiN | 20 | Water | <10 | 33 | 21 | 16 |
| Example 5 | | | | | | | | | | |

Incidentally, in Tables, “C₄F₉—C₂H₄—P(O)(OH)₂” means perfluorobutylethylphosphonic acid, “C₁₂H₂₅P(O)(OH)₂” means dodecylphosphonic acid, “C₁₀H₂₁P(O)(OH)₂” means decylphosphonic acid, “C₈H₁₇P(O)(OH)₂” means octylphosphonic acid, “C₆H₁₃P(O)(OH)₂” means hexylphosphonic acid, “C₁₀H₂₁P(O)(OC₂H₅)₂” means diethyl decylphosphonate, “C₈F₁₇—C₂H₄—NH₂” means perfluorooctylethylamine, “C₆F₁₃—C₂H₄—NH₂” means perfluorohexylethylamine, “C₈H₁₇NH₂” means octylamine, “C₈H₁₇NHC₈H₁₇” means dioctylamine, and “C₇H₁₅CONHOH” means octanohydroxamic acid. Furthermore, “PGMEA/iPA-0.1” means a solvent obtained by combining PGMEA and iPA at a mass ratio of 99.9:0.1. “DGEEA” means diethylene glycol monoethyl ether acetate. “DGEEA/iPA-0.1” means a solvent obtained by combining DGEEA and iPA at a mass ratio of 99.9:0.1. “Water/iPA-30” means a solvent obtained by combining water and iPA at a mass ratio of 70:30. Moreover, water means pure water.

### Comparative Example 1

The procedure of Example 12 was repeated with the exception that butylphosphonic acid [C₄H₉P(O)(OH)₂] was used as the water-repellent protective film forming agent and the protective film forming agent concentration was adjusted to 0.007 mass %. The results were as shown in Table 2; more specifically, a contact angle in the case where the rinsing time after a water-repellent protective film forming step was 5 seconds was 50°, a contact angle in the case where the rinsing time was 30 seconds was 48°, and a contact angle in the case where the rinsing time was 60 seconds was 47°, which means that the water repellency on the wafer surface was decreased by the rinsing treatment so that it was not possible to maintain a sufficient water repellency on the wafer surface.

### Comparative Example 2

The procedure of Example 34 was repeated with the exception that butylamine [C₄H₉NH₂] was used as the water-repellent protective film forming agent. The results were as shown in Table 2; more specifically, a contact angle in the case where the rinsing time after the water-repellent protective film forming step was 5 seconds was 58°, a contact angle in the case where the rinsing time was 30 seconds was 43°, and a contact angle in the case where the rinsing time was 60 seconds was 36°, which means that the water repellency on the wafer surface was decreased by the rinsing treatment so that it was not possible to maintain a sufficient water repellency on the wafer surface.

### Comparative Example 3

The procedure of Example 37 was repeated with the exception that acetohydroxamic acid [CH₃CONHOH] was used as the water-repellent protective film forming agent. The results were as shown in Table 2; more specifically, a contact angle in the case where the rinsing time after the water-repellent protective film forming step was 5 seconds was 33°, a contact angle in the case where the rinsing time was 30 seconds was 28°, and a contact angle in the case where the rinsing time was 60 seconds was 24°, from which it was confirmed that a sufficient water repellency was not imparted the wafer surface.

### Comparative Example 4

The procedure of Example 43 was repeated with the exception that butylphosphonic acid [C₄H₉P(O)(OH)₂] was used as the water-repellent protective film forming agent. The results were as shown in Table 2; more specifically, a contact angle in the case where the rinsing time after the water-repellent protective film forming step was 5 seconds was 65°, a contact angle in the case where the rinsing time was 30 seconds was 30°, and a contact angle in the case where the rinsing time was 60 seconds was 25°, which means that the water repellency on the wafer surface was decreased by the rinsing treatment so that it was not possible to maintain a sufficient water repellency on the wafer surface.

### Comparative Example 5

The procedure of Example 54 was repeated with the exception that acetohydroxamic acid [CH₃CONHOH] was used as the water-repellent protective film forming agent. The results were as shown in Table 2; more specifically, a contact angle in the case where the rinsing time after the water-repellent protective film forming step was 5 seconds was 33°, a contact angle in the case where the rinsing time was 30 seconds was 21°, and a contact angle in the case where the rinsing time was 60 seconds was 16°, from which it was confirmed that a sufficient water repellency was not imparted the wafer surface.

### Example 55

(II-1) Preparation of Liquid Chemical for forming Water-Repellent Protective Film

A liquid chemical for forming a water-repellent protective film was prepared in the same manner as Example 1.

(II-2) Wafer Cleaning Step (Pretreatment Step)

As a pretreatment step 2, a wafer having a smooth tungsten film (a silicon wafer formed having on its surface a tungsten layer of 50 nm thickness) was immersed in 1 mass % aqueous ammonia for 1 minute at room temperature, and then immersed in pure water for 1 minute. Furthermore, as a pretreatment step 3, the wafer was immersed in iPA for 1 minute.

(II-3) From Step of Forming Water-Repellent Protective Film on Wafer to Rinsing Liquid Removal Step

In a protective film forming step, the wafer having a tungsten film was immersed in the liquid chemical for forming a protective film which liquid chemical had been prepared according to the “(II-1) Preparation of Liquid Chemical for forming Water-Repellent Protective Film” section, for 10 minutes at 40° C., thereby causing adsorption of a protective film forming agent to form a protective film on the wafer surface. Thereafter, a rinsing treatment step was conducted in such a manner as to immerse the wafer having a tungsten film in iPA for 5 seconds, 30 seconds or 60 seconds. In a rinsing liquid removal step, the wafer having a tungsten film was taken out of iPA, followed by blowing air to remove the iPA from the surface.

As a result of evaluating the thus obtained wafer having a tungsten film in a manner discussed in the above [Method for Evaluating Wafer to which Liquid Chemical for forming Protective Film is supplied] section, a wafer having an initial contact angle of smaller than 10° before the protective film formation was confirmed to have a contact angle of 92° in the case where the rinsing time after the protective film formation was 5 seconds, as shown in Table 3, from which it was confirmed that the water repellency-imparting effect was excellently obtained. Likewise, a wafer in the case where the rinsing time after the protective film formation was 30 seconds had a contact angle of 89° and a wafer in the case where the rinsing time after the protective film formation was 60 seconds had a contact angle of 84°, from which it was confirmed that the water repellency was favorably maintained even after the rinsing treatment.

TABLE 3

| | | | | | Temperature of | | | | | |
|---|---|---|---|---|---|---|---|---|---|---|
| | Liquid Chemical for Forming Protective Film | | | | Liquid Chemical | | Contact Angle [°] | | | |
| | | Protective | | | During Water- | | Before | After Protective Film | | |
| | | Film Form- | | | Repellent | Rins- | Protec- | is formed | | |
| | | ing Agent | | | Protective | ing | tive | Rinsing | Rinsing | Rinsing |
| | Protective Film | Concentration | | Wa- | Film Forming | Liq- | Film is | Time | Time | Time |
| | Forming Agent | [mass %] | Solvent | fer | Step [° C.] | uid | formed | [5 sec] | [30 sec] | [60 sec] |
| Example 55 | C₆F₁₃—C₂H₄—P(O)(OH)₂ | 0.01 | PGMEA | W | 40 | iPA | <10 | 92 | 89 | 84 |
| Example 56 | C₆F₁₃—C₂H₄—P(O)(OH)₂ | 0.03 | PGMEA | W | 40 | iPA | <10 | 95 | 90 | 84 |
| Example 57 | C₆F₁₃—C₂H₄—P(O)(OH)₂ | 0.01 | PGMEA | W | 60 | iPA | <10 | 98 | 95 | 90 |
| Example 58 | C₆F₁₃—C₂H₄—P(O)(OH)₂ | 0.03 | PGMEA | W | 60 | iPA | <10 | 100 | 96 | 91 |
| Example 59 | C₄F₉—C₂H₄—P(O)(OH)₂ | 0.01 | DGEEA | W | 40 | iPA | <10 | 93 | 91 | 91 |
| Example 60 | C₁₀H₂₁P(O)(OH)₂ | 0.1 | PGMEA | W | 40 | iPA | <10 | 83 | 72 | 66 |
| Example 61 | C₆H₁₃P(O)(OH)₂ | 0.1 | PGMEA | W | 60 | iPA | <10 | 69 | 57 | 50 |
| Example 62 | C₁₀H₂₁P(O)(OC₂H₅)₂ | 0.1 | PGMEA | W | 40 | iPA | <10 | 64 | 54 | 50 |
| Example 63 | C₈F₁₇—C₂H₄—NH₂ | 0.1 | iPA | W | 40 | iPA | <10 | 91 | 91 | 91 |
| Example 64 | C₆F₁₃—C₂H₄—NH₂ | 0.1 | iPA | W | 40 | iPA | <10 | 95 | 94 | 94 |
| Example 65 | C₆F₁₃—C₂H₄—NH₂ | 0.05 | iPA | W | 40 | iPA | <10 | 94 | 93 | 93 |
| Example 66 | C₆F₁₃—C₂H₄—NH₂ | 1 | iPA | W | 40 | iPA | <10 | 96 | 96 | 96 |
| Example 67 | C₆F₁₃—C₂H₄—NH₂ | 10 | iPA | W | 40 | iPA | <10 | 97 | 97 | 97 |
| Example 68 | C₆F₁₃—C₂H₄—NH₂ | 10 | iPA | W | 60 | iPA | <10 | 98 | 98 | 98 |
| Example 69 | C₁₄H₂₉NH₂ | 1 | iPA | W | 40 | iPA | <10 | 89 | 88 | 88 |
| Example 70 | C₁₄H₂₉NH₂ | 0.05 | DGEEA/ | W | 40 | iPA | <10 | 89 | 88 | 88 |
| | | | iPA-0.5 | | | | | | | |
| Example 71 | C₁₂H₂₅NH₂ | 1 | iPA | W | 40 | iPA | <10 | 84 | 83 | 83 |
| Example 72 | C₈H₁₇NH₂ | 10 | iPA | W | 60 | iPA | <10 | 89 | 86 | 83 |
| Example 73 | C₆H₁₃NH₂ | 10 | iPA | W | 60 | iPA | <10 | 86 | 82 | 80 |
| Example 74 | C₈H₁₇NHC₈H₁₇ | 10 | iPA | W | 60 | iPA | <10 | 89 | 89 | 88 |
| Example 75 | C₆H₁₃NHC₆H₁₃ | 10 | iPA | W | 60 | iPA | <10 | 84 | 81 | 79 |
| Example 76 | C₁₁H₂₃C₃H₅N₂ | 0.01 | PGMEA | W | 40 | iPA | <10 | 91 | 85 | 83 |
| Example 77 | C₈F₁₇—C₂H₄—NH₂ | 0.1 | iPA | W | 40 | Water | <10 | 91 | 91 | 91 |
| Example 78 | C₁₄H₂₉NH₂ | 0.05 | DGEEA/ | W | 40 | Water | <10 | 89 | 84 | 82 |
| | | | iPA-0.5 | | | | | | | |
| Example 79 | C₁₂H₂₅NH₂ | 1 | iPA | W | 40 | Water | <10 | 84 | 80 | 77 |
| Example 80 | C₆F₁₃—C₂H₄—NH₂ | 10 | iPA | W | 60 | Water | <10 | 98 | 90 | 85 |
| Example 81 | C₆H₁₃NH₂ | 10 | iPA | W | 60 | Water | <10 | 86 | 68 | 58 |
| Example 82 | C₁₁H₂₃C₃H₅N₂ | 0.01 | PGMEA | W | 40 | Water | <10 | 91 | 85 | 83 |
| Comparative | C₄H₉NH₂ | 10 | iPA | W | 60 | iPA | <10 | 58 | 43 | 32 |
| Example 6 | | | | | | | | | | |
| Comparative | C₃H₇C₃H₅N₂ | 0.01 | PGMEA | W | 40 | iPA | <10 | 37 | 32 | 25 |
| Example 7 | | | | | | | | | | |
| Comparative | C₄H₉NH₂ | 10 | iPA | W | 60 | Water | <10 | 58 | 30 | 12 |
| Example 8 | | | | | | | | | | |
| Comparative | C₃H₇C₃H₅N₂ | 0.01 | PGMEA | W | 40 | Water | <10 | 37 | 21 | 10 |
| Example 9 | | | | | | | | | | |

### Examples 56 to 82

Upon modifying the conditions employed in Example 55 (as to the protective film forming agent, the solvent for the liquid chemical for forming a protective film, the protective film forming agent concentration, the temperature of the liquid chemical during the water-repellent protective film forming step, and the rinsing liquid), a surface treatment was conducted on each wafer in the same manner as in Example 55, followed by evaluation of these. The results are shown in Table 3.

Incidentally, in Table, “C₁₄H₂₉NH₂” means tetradecylamine, “C₁₂H₂₅NH₂” means dodecylamine, “C₆H₁₃NH₂” means hexylamine, “C₆H₁₃NHC₆H₁₃” means dihexylamine, and “C₁₁H₂₃C₃H₅N₂” means 2-undecyl-2-imidazoline. In addition, “DGEEA/iPA-0.5” means a solvent obtained by combining DGEEA and iPA at a mass ratio of 99.5:0.5.

### Comparative Example 6

The procedure of Example 73 was repeated with the exception that butylamine [C₄H₉NH₂] was used as the water-repellent protective film forming agent. The results were as shown in Table 3; more specifically, a contact angle in the case where the rinsing time after the water-repellent protective film forming step was 5 seconds was 58°, a contact angle in the case where the rinsing time was 30 seconds was 43°, and a contact angle in the case where the rinsing time was 60 seconds was 32°, which means that the water repellency on the wafer surface was decreased by the rinsing treatment so that it was not possible to maintain a sufficient water repellency on the wafer surface.

### Comparative Example 7

The procedure of Example 76 was repeated with the exception that 2-propyl-2-imidazoline [C₃H₇C₃H₅N₂] was used as the water-repellent protective film forming agent. The results were as shown in Table 3; more specifically, a contact angle in the case where the rinsing time after the water-repellent protective film forming step was 5 seconds was 37°, a contact angle in the case where the rinsing time was 30 seconds was 32°, and a contact angle in the case where the rinsing time was 60 seconds was 25°, from which it was confirmed that a sufficient water repellency was not imparted the wafer surface.

### Comparative Example 8

The procedure of Example 81 was repeated with the exception that butylamine [C₄H₉NH₂] was used as the water-repellent protective film forming agent. The results were as shown in Table 3; more specifically, a contact angle in the case where the rinsing time after the water-repellent protective film forming step was 5 seconds was 58°, a contact angle in the case where the rinsing time was 30 seconds was 30°, and a contact angle in the case where the rinsing time was 60 seconds was 12°, which means that the water repellency on the wafer surface was decreased by the rinsing treatment so that it was not possible to maintain a sufficient water repellency on the wafer surface.

### Comparative Example 9

The procedure of Example 82 was repeated with the exception that 2-propyl-2-imidazoline [C₃H₇C₃H₅N₂] was used as the water-repellent protective film forming agent. The results were as shown in Table 3; more specifically, a contact angle in the case where the rinsing time after the water-repellent protective film forming step was 5 seconds was 37°, a contact angle in the case where the rinsing time was 30 seconds was 21°, and a contact angle in the case where the rinsing time was 60 seconds was 10°, from which it was confirmed that a sufficient water repellency was not imparted the wafer surface.

### Example 83

(III-1) Preparation of Liquid Chemical for forming Water-Repellent Protective Film

A liquid chemical for forming a water-repellent protective film was prepared in the same manner as Example 1.

(III-2) Wafer Cleaning Step (Pretreatment Step)

As a pretreatment step 2, a wafer having a smooth ruthenium film (a silicon wafer formed having on its surface a ruthenium layer of 300 nm thickness) was immersed in 1 mass % aqueous ammonia for 1 minute at room temperature, and then immersed in pure water for 1 minute. Furthermore, as a pretreatment step 3, the wafer was immersed in iPA for 1 minute.

(III-3) From Step of Forming Water-Repellent Protective Film on Wafer to Rinsing Liquid Removal Step

In a protective film forming step, the wafer having a ruthenium film was immersed in the liquid chemical for forming a protective film which liquid chemical had been prepared according to the “(III-1) Preparation of Liquid Chemical for forming Water-Repellent Protective Film” section, for 10 minutes at 20° C., thereby causing adsorption of a protective film forming agent to form a protective film on the wafer surface. Thereafter, a rinsing treatment step was conducted in such a manner as to immerse the wafer having a ruthenium film in iPA for 5 seconds, 30 seconds or 60 seconds. In a rinsing liquid removal step, the wafer having a ruthenium film was taken out of iPA, followed by blowing air to remove the iPA from the surface.

As a result of evaluating the thus obtained wafer having a ruthenium film in a manner discussed in the above [Method for Evaluating Wafer to which Liquid Chemical for forming Protective Film is supplied] section, a wafer having an initial contact angle of smaller than 10° before the protective film formation was confirmed to have a contact angle of 85° in the case where the rinsing time after the protective film formation was 5 seconds, as shown in Table 4, from which it was confirmed that the water repellency-imparting effect was excellently obtained. Likewise, a wafer in the case where the rinsing time after the protective film formation was 30 seconds had a contact angle of 84° and a wafer in the case where the rinsing time after the protective film formation was 60 seconds had a contact angle of 83°, from which it was confirmed that the water repellency was favorably maintained even after the rinsing treatment.

TABLE 4

| | | | | | Temperature of | | | | | |
|---|---|---|---|---|---|---|---|---|---|---|
| | Liquid Chemical for Forming Protective Film | | | | Liquid Chemical | | Contact Angle [°] | | | |
| | | Protective | | | During Water- | | Before | After Protective Film | | |
| | | Film Form- | | | Repellent | Rins- | Protec- | is formed | | |
| | | ing Agent | | | Protective | ing | tive | Rinsing | Rinsing | Rinsing |
| | Protective Film | Concentration | | Wa- | Film Forming | Liq- | Film is | Time | Time | Time |
| | Forming Agent | [mass %] | Solvent | fer | Step [° C.] | uid | formed | [5 sec] | [30 sec] | [60 sec] |
| Example 83 | C₆F₁₃—C₂H₄—P(O)(OH)₂ | 0.01 | PGMEA | Ru | 20 | iPA | <10 | 85 | 84 | 83 |
| Example 84 | C₆F₁₃—C₂H₄—P(O)(OH)₂ | 0.01 | Water/iPA-30 | Ru | 20 | iPA | <10 | 85 | 83 | 82 |
| Example 85 | C₆F₁₃—C₂H₄—P(O)(OH)₂ | 0.1 | Water/iPA-30 | Ru | 20 | iPA | <10 | 90 | 88 | 88 |
| Example 86 | C₆F₁₃—C₂H₄—P(O)(OH)₂ | 0.5 | Water/iPA-30 | Ru | 20 | iPA | <10 | 92 | 90 | 89 |
| Example 87 | C₆F₁₃—C₂H₄—P(O)(OH)₂ | 0.01 | Water/iPA-30 | Ru | 60 | iPA | <10 | 92 | 91 | 90 |
| Example 88 | C₆F₁₃—C₂H₄—P(O)(OH)₂ | 0.5 | Water/iPA-30 | Ru | 60 | iPA | <10 | 95 | 94 | 94 |
| Example 89 | C₄F₉—C₂H₄—P(O)(OH)₂ | 0.01 | DGEEA | Ru | 20 | iPA | <10 | 85 | 83 | 83 |
| Example 90 | C₁₀H₂₁P(O)(OH)₂ | 1 | PGMEA | Ru | 60 | iPA | <10 | 76 | 71 | 69 |
| Example 91 | C₈H₁₇P(O)(OH)₂ | 1 | PGMEA | Ru | 60 | iPA | <10 | 72 | 68 | 65 |
| Example 92 | C₆H₁₃P(O)(OH)₂ | 1 | PGMEA | Ru | 60 | iPA | <10 | 65 | 61 | 58 |
| Example 93 | C₁₀H₂₁P(O)(OC₂H₅)₂ | 1 | PGMEA | Ru | 60 | iPA | <10 | 70 | 68 | 65 |
| Example 94 | C₈F₁₇—C₂H₄—NH₂ | 0.1 | iPA | Ru | 20 | iPA | <10 | 117 | 117 | 117 |
| Example 95 | C₈F₁₇—C₂H₄—NH₂ | 0.05 | iPA | Ru | 20 | iPA | <10 | 115 | 115 | 115 |
| Example 96 | C₆F₁₃—C₂H₄—NH₂ | 0.05 | iPA | Ru | 20 | iPA | <10 | 107 | 105 | 104 |
| Example 97 | C₆F₁₃—C₂H₄—NH₂ | 1 | iPA | Ru | 20 | iPA | <10 | 109 | 108 | 108 |
| Example 98 | C₆F₁₃—C₂H₄—NH₂ | 3 | iPA | Ru | 20 | iPA | <10 | 111 | 109 | 109 |
| Example 99 | C₆F₁₃—C₂H₄—NH₂ | 5 | iPA | Ru | 20 | iPA | <10 | 112 | 110 | 110 |
| Example 100 | C₆F₁₃—C₂H₄—NH₂ | 1 | iPA | Ru | 40 | iPA | <10 | 112 | 111 | 111 |
| Example 101 | C₆F₁₃—C₂H₄—NH₂ | 5 | iPA | Ru | 60 | iPA | <10 | 112 | 112 | 112 |
| Example 102 | C₆F₁₃—C₂H₄—NH₂ | 10 | iPA | Ru | 60 | iPA | <10 | 112 | 112 | 112 |
| Example 103 | C₁₄H₂₉NH₂ | 0.05 | DGEEA/ | Ru | 20 | iPA | <10 | 103 | 101 | 100 |
| | | | iPA-0.5 | | | | | | | |
| Example 104 | C₈H₁₇NH₂ | 3 | DGEEA | Ru | 20 | iPA | <10 | 92 | 92 | 92 |
| Example 105 | C₈H₁₇NH₂ | 1 | iPA | Ru | 20 | iPA | <10 | 91 | 91 | 91 |
| Example 106 | C₈H₁₇NH₂ | 1 | iPA | Ru | 40 | iPA | <10 | 94 | 94 | 94 |
| Example 107 | C₆H₁₃NH₂ | 1 | iPA | Ru | 20 | iPA | <10 | 84 | 84 | 84 |
| Example 108 | C₆H₁₃NH₂ | 1 | iPA | Ru | 40 | iPA | <10 | 88 | 87 | 86 |
| Example 109 | C₆H₁₃NH₂ | 3 | DGEEA | Ru | 20 | iPA | <10 | 88 | 88 | 88 |
| Example 110 | C₆F₁₃—CH₂—NH₂ | 1 | iPA | Ru | 40 | iPA | <10 | 76 | 72 | 69 |
| Example 111 | C₆H₁₃NH₂ | 5 | iPA | Ru | 60 | iPA | <10 | 96 | 95 | 95 |
| Example 112 | C₈H₁₇NHC₈H₁₇ | 1 | iPA | Ru | 20 | iPA | <10 | 74 | 69 | 66 |
| Example 113 | C₈H₁₇NHC₈H₁₇ | 1 | iPA | Ru | 40 | iPA | <10 | 90 | 88 | 86 |
| Example 114 | C₆H₁₃NHC₆H₁₃ | 5 | iPA | Ru | 60 | iPA | <10 | 89 | 88 | 87 |
| Example 115 | C₁₂H₂₅NCO | 3 | PGMEA | Ru | 20 | iPA | <10 | 93 | 93 | 93 |
| Example 116 | C₁₂H₂₅NCO | 3 | PGMEA | Ru | 60 | iPA | <10 | 95 | 94 | 94 |
| Example 117 | C₈H₁₇NCO | 3 | PGMEA | Ru | 20 | iPA | <10 | 77 | 74 | 73 |
| Example 118 | C₄H₉NCO | 10 | PGMEA | Ru | 60 | iPA | <10 | 77 | 74 | 71 |
| Example 119 | C₁₂H₂₅SH | 3 | PGMEA | Ru | 20 | iPA | <10 | 93 | 93 | 93 |
| Example 120 | C₈H₁₇SH | 3 | PGMEA | Ru | 20 | iPA | <10 | 84 | 83 | 82 |
| Example 121 | C₄H₉SH | 10 | PGMEA | Ru | 60 | iPA | <10 | 75 | 72 | 69 |
| Example 122 | C₁₁H₂₃C₃H₅N₂ | 0.01 | PGMEA | Ru | 20 | iPA | <10 | 84 | 82 | 82 |
| Example 123 | C₁₁H₂₃C₃H₅N₂ | 0.01 | PGMEA | Ru | 60 | iPA | <10 | 97 | 96 | 95 |

### Examples 84 to 145

Upon modifying the conditions employed in Example 83 (as to the protective film forming agent, the protective film forming agent concentration, the solvent for the liquid chemical for forming a protective film, the temperature of the liquid chemical during the water-repellent protective film forming step, and the rinsing liquid), a surface treatment was conducted on each wafer in the same manner as in Example 83, followed by evaluation of these. The results are shown in Tables 4 and 5.

TABLE 5

| | | | | | Temperature of | | | | | |
|---|---|---|---|---|---|---|---|---|---|---|
| | Liquid Chemical for Forming Protective Film | | | | Liquid Chemical | | Contact Angle [°] | | | |
| | | Protective | | | During Water- | | Before | After Protective Film | | |
| | | Film Form- | | | Repellent | Rins- | Protec- | is formed | | |
| | | ing Agent | | | Protective | ing | tive | Rinsing | Rinsing | Rinsing |
| | Protective Film | Concentration | | Wa- | Film Forming | Liq- | Film is | Time | Time | Time |
| | Forming Agent | [mass %] | Solvent | fer | Step [° C.] | uid | formed | [5 sec] | [30 sec] | [60 sec] |
| Example 124 | C₆F₁₃—C₂H₄—P(O)(OH)₂ | 0.01 | PGMEA | Ru | 20 | Water | <10 | 85 | 75 | 67 |
| Example 125 | C₄F₉—C₂H₄—P(O)(OH)₂ | 0.01 | DGEEA | Ru | 20 | Water | <10 | 85 | 83 | 80 |
| Example 126 | C₆F₁₃—C₂H₄—P(O)(OH)₂ | 0.01 | Water/iPA-30 | Ru | 20 | Water | <10 | 85 | 72 | 64 |
| Example 127 | C₆F₁₃—C₂H₄—P(O)(OH)₂ | 0.1 | Water/iPA-30 | Ru | 20 | Water | <10 | 90 | 80 | 72 |
| Example 128 | C₆F₁₃—C₂H₄—P(O)(OH)₂ | 0.5 | Water/iPA-30 | Ru | 20 | Water | <10 | 92 | 87 | 78 |
| Example 129 | C₆F₁₃—C₂H₄—P(O)(OH)₂ | 0.01 | Water/iPA-30 | Ru | 60 | Water | <10 | 92 | 86 | 84 |
| Example 130 | C₆F₁₃—C₂H₄—P(O)(OH)₂ | 0.5 | Water/iPA-30 | Ru | 60 | Water | <10 | 95 | 90 | 86 |
| Example 131 | C₈F₁₇—C₂H₄—NH₂ | 0.1 | iPA | Ru | 20 | Water | <10 | 117 | 117 | 117 |
| Example 132 | C₆F₁₃—C₂H₄—NH₂ | 0.1 | iPA | Ru | 20 | Water | <10 | 109 | 109 | 109 |
| Example 133 | C₆F₁₃—C₂H₄—NH₂ | 10 | iPA | Ru | 60 | Water | <10 | 110 | 110 | 110 |
| Example 134 | C₁₄H₂₉NH₂ | 0.05 | DGEEA/ | Ru | 20 | Water | <10 | 103 | 100 | 99 |
| | | | iPA-0.5 | | | | | | | |
| Example 135 | C₈H₁₇NH₂ | 3 | DGEEA | Ru | 20 | Water | <10 | 92 | 91 | 90 |
| Example 136 | C₈H₁₇NH₂ | 1 | iPA | Ru | 40 | Water | <10 | 94 | 93 | 92 |
| Example 137 | C₆H₁₃NH₂ | 1 | iPA | Ru | 20 | Water | <10 | 84 | 72 | 67 |
| Example 138 | C₆H₁₃NH₂ | 1 | iPA | Ru | 40 | Water | <10 | 88 | 85 | 80 |
| Example 139 | C₁₂H₂₅NCO | 3 | PGMEA | Ru | 20 | Water | <10 | 93 | 92 | 91 |
| Example 140 | C₄H₉NCO | 10 | PGMEA | Ru | 60 | Water | <10 | 77 | 73 | 68 |
| Example 141 | C₁₂H₂₅SH | 3 | PGMEA | Ru | 20 | Water | <10 | 93 | 92 | 92 |
| Example 142 | C₈H₁₇SH | 3 | PGMEA | Ru | 20 | Water | <10 | 84 | 82 | 81 |
| Example 143 | C₄H₉SH | 10 | PGMEA | Ru | 60 | Water | <10 | 75 | 72 | 69 |
| Example 144 | C₁₁H₂₃C₃H₅N₂ | 0.01 | PGMEA | Ru | 20 | Water | <10 | 84 | 80 | 78 |
| Example 145 | C₁₁H₂₃C₃H₅N₂ | 0.01 | PGMEA | Ru | 60 | Water | <10 | 97 | 94 | 92 |
| Comparative | C₄H₉NH₂ | 1 | iPA | Ru | 20 | iPA | <10 | 58 | 48 | 41 |
| Example 10 | | | | | | | | | | |
| Comparative | C₃H₇NCO | 10 | PGMEA | Ru | 60 | iPA | <10 | 50 | 34 | 29 |
| Example 11 | | | | | | | | | | |
| Comparative | C₃H₇SH | 10 | PGMEA | Ru | 60 | iPA | <10 | 52 | 40 | 35 |
| Example 12 | | | | | | | | | | |
| Comparative | C₃H₇C₃H₅N₂ | 0.01 | PGMEA | Ru | 60 | iPA | <10 | 51 | 38 | 21 |
| Example 13 | | | | | | | | | | |
| Comparative | C₄H₉NH₂ | 1 | iPA | Ru | 20 | Water | <10 | 58 | 44 | 35 |
| Example 14 | | | | | | | | | | |
| Comparative | C₃H₇NCO | 10 | PGMEA | Ru | 60 | Water | <10 | 50 | 31 | 19 |
| Example 15 | | | | | | | | | | |
| Comparative | C₃H₇SH | 10 | PGMEA | Ru | 60 | Water | <10 | 52 | 34 | 23 |
| Example 16 | | | | | | | | | | |
| Comparative | C₃H₇C₃H₅N₂ | 0.01 | PGMEA | Ru | 60 | Water | <10 | 51 | 32 | 19 |
| Example 17 | | | | | | | | | | |

Incidentally, in Tables, “C₆F₁₃—CH₂—NH₂” means perfluorohexylmethylamine, “C₁₂H₂₅NCO” means dodecylisocyanate, “C₈H₁₇NCO” means octylisocyanate, “C₄H₉NCO” means butylisocyanate, “C₁₂H₂₅SH” means dodecanethiol, “C₈H₁₇SH” means octanethiol, and “C₄H₉SH” means butanethiol.

### Comparative Example 10

The procedure of Example 107 was repeated with the exception that butylamine [C₄H₉NH₂] was used as the water-repellent protective film forming agent. The results were as shown in Table 5; more specifically, a contact angle in the case where the rinsing time after the water-repellent protective film forming step was 5 seconds was 58°, a contact angle in the case where the rinsing time was 30 seconds was 48°, and a contact angle in the case where the rinsing time was 60 seconds was 41°, which means that the water repellency on the wafer surface was decreased by the rinsing treatment so that it was not possible to maintain a sufficient water repellency on the wafer surface.

### Comparative Example 11

The procedure of Example 118 was repeated with the exception that propylisocyanate [C₃H₇NCO] was used as the water-repellent protective film forming agent. The results were as shown in Table 5; more specifically, a contact angle in the case where the rinsing time after the water-repellent protective film forming step was 5 seconds was 50°, a contact angle in the case where the rinsing time was 30 seconds was 34°, and a contact angle in the case where the rinsing time was 60 seconds was 29°, which means that the water repellency on the wafer surface was decreased by the rinsing treatment so that it was not possible to maintain a sufficient water repellency on the wafer surface.

### Comparative Example 12

The procedure of Example 121 was repeated with the exception that propanethiol [C₃H₇SH] was used as the water-repellent protective film forming agent. The results were as shown in Table 5; more specifically, a contact angle in the case where the rinsing time after the water-repellent protective film forming step was 5 seconds was 52°, a contact angle in the case where the rinsing time was 30 seconds was 40°, and a contact angle in the case where the rinsing time was 60 seconds was 35°, which means that the water repellency on the wafer surface was decreased by the rinsing treatment so that it was not possible to maintain a sufficient water repellency on the wafer surface.

### Comparative Example 13

The procedure of Example 123 was repeated with the exception that 2-propyl-2-imidazoline [C₃H₇C₃H₅N₂] was used as the water-repellent protective film forming agent. The results were as shown in Table 5; more specifically, a contact angle in the case where the rinsing time after the water-repellent protective film forming step was 5 seconds was 51°, a contact angle in the case where the rinsing time was 30 seconds was 38°, and a contact angle in the case where the rinsing time was 60 seconds was 21°, which means that the water repellency on the wafer surface was decreased by the rinsing treatment so that it was not possible to maintain a sufficient water repellency on the wafer surface.

### Comparative Example 14

The procedure of Example 137 was repeated with the exception that butylamine [C₄H₉NH₂] was used as the water-repellent protective film forming agent. The results were as shown in Table 5; more specifically, a contact angle in the case where the rinsing time after the water-repellent protective film forming step was 5 seconds was 58°, a contact angle in the case where the rinsing time was 30 seconds was 44°, and a contact angle in the case where the rinsing time was 60 seconds was 35°, which means that the water repellency on the wafer surface was decreased by the rinsing treatment so that it was not possible to maintain a sufficient water repellency on the wafer surface.

### Comparative Example 15

The procedure of Example 140 was repeated with the exception that propylisocyanate [C₃H₇NCO] was used as the water-repellent protective film forming agent. The results were as shown in Table 5; more specifically, a contact angle in the case where the rinsing time after the water-repellent protective film forming step was 5 seconds was 50°, a contact angle in the case where the rinsing time was 30 seconds was 31°, and a contact angle in the case where the rinsing time was 60 seconds was 19°, which means that the water repellency on the wafer surface was decreased by the rinsing treatment so that it was not possible to maintain a sufficient water repellency on the wafer surface.

### Comparative Example 16

The procedure of Example 143 was repeated with the exception that propanethiol [C₃H₇SH] was used as the water-repellent protective film forming agent. The results were as shown in Table 5; more specifically, a contact angle in the case where the rinsing time after the water-repellent protective film forming step was 5 seconds was 52°, a contact angle in the case where the rinsing time was 30 seconds was 34°, and a contact angle in the case where the rinsing time was 60 seconds was 23°, which means that the water repellency on the wafer surface was decreased by the rinsing treatment so that it was not possible to maintain a sufficient water repellency on the wafer surface.

### Comparative Example 17

The procedure of Example 145 was repeated with the exception that 2-propyl-2-imidazoline [C₃H₇C₃H₅N₂] was used as the water-repellent protective film forming agent. The results were as shown in Table 5; more specifically, a contact angle in the case where the rinsing time after the water-repellent protective film forming step was 5 seconds was 51°, a contact angle in the case where the rinsing time was 30 seconds was 32°, and a contact angle in the case where the rinsing time was 60 seconds was 19°, which means that the water repellency on the wafer surface was decreased by the rinsing treatment so that it was not possible to maintain a sufficient water repellency on the wafer surface.

### EXPLANATION OF REFERENCE NUMERALS

1 Wafer

2 Uneven pattern of a surface of the wafer

3 Projected portions of the pattern

4 Recessed portions of the pattern

5 Widths of the recessed portions

6 Heights of the projected portions

7 Widths of the projected portions

8 Liquid chemical for forming a water-repellent protective film, retained in the recessed portions 4

9 Rinsing liquid retained in the recessed portions 4

10 Water-repellent protective film

1. A liquid chemical for forming a water-repellent protective film, comprising:
a water-repellent protective film forming agent for forming a water-repellent protective film on a wafer having at its surface an uneven pattern and containing at least one kind of element selected from the group consisting of titanium, tungsten, aluminum, copper, tin, tantalum and ruthenium at surfaces of recessed portions of the uneven pattern, the water-repellent protective film being formed at least on the surfaces of the recessed portions by retaining the liquid chemical at least on the recessed portions of the wafer before a rinsing treatment step of rinsing the wafer surface with a rinsing liquid consisting only of a protic polar solvent or a rinsing liquid containing a protic polar solvent as the principal component; and
a solvent,
wherein the water-repellent protective film forming agent is at least one kind of compound represented by the following general formulas [1] to [3] 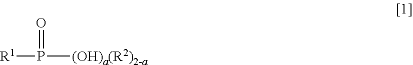
wherein R¹ represents a C₆-C₁₈ monovalent hydrocarbon group, the hydrogen elements of which may partially or entirely be replaced with a fluorine element(s),
wherein R² mutually independently represents a monovalent organic group having a C₁-C₁₈ hydrocarbon group the hydrogen elements of which may partially or entirely be replaced with a fluorine element(s), and wherein “a” is an integer of from 0 to 2.
(R³)_{b}(R⁴)_{c}NH_{3-b- c} [2]
wherein R³ mutually independently represents a C₆-C₁₈ monovalent hydrocarbon group the hydrogen elements of which may partially or entirely be replaced with a fluorine element(s),
wherein R⁴ mutually independently represents a C₁-C₃ monovalent hydrocarbon group the hydrogen elements of which may partially or entirely be replaced with a fluorine element(s),
wherein“b” is an integer of from 1 to 3, “c” is an integer of from 0 to 2, and the total of “b” and “c” is an integer of from 1 to 3.
R⁵(X)_{d} [3]
wherein formula [3] represents a compound obtained by mutually independently substituting “d” hydrogen element(s) or fluorine element(s) of R⁵ which represents a C₄-C₁₈ hydrocarbon, the hydrogen elements of which may partially or entirely be replaced with a fluorine element(s) with at least one group indicated by X and selected from the group consisting of an isocyanate group, mercapto group, —CONHOH group and a cyclic structure containing a nitrogen element, wherein “d” is an integer of from 1 to 6.)

2. A liquid chemical for forming a water-repellent protective film, as claimed in claim 1, wherein “a” in the general formula [1] is 2.

3. A liquid chemical for forming a water-repellent protective film, as claimed in claim 1, wherein R¹ in the general formula [1] is a C₈-C₁₈ monovalent hydrocarbon group the hydrogen elements of which may partially or entirely be replaced with a fluorine element(s).

4. A liquid chemical for forming a water-repellent protective film, as claimed in claim 1, wherein “b” in the general formula [2] is 1.

5. A liquid chemical for forming a water-repellent protective film, as claimed in claim 1, wherein R³ in the general formula [2] is a C₈-C₁₈ monovalent hydrocarbon group the hydrogen elements of which may partially or entirely be replaced with a fluorine element(s).

6. A liquid chemical for forming a water-repellent protective film, as claimed in claim 1, wherein R⁵ in the general formula [3] has a carbon number of 6 to 18.

7. A water-repellent protective film formed on a wafer having at its surface an uneven pattern and containing at least one kind of element selected from the group consisting of titanium, tungsten, aluminum, copper, tin, tantalum and ruthenium at surfaces of recessed portions of the uneven pattern, the water-repellent protective film being formed at least on the surfaces of the recessed portions by retaining the liquid chemical for forming water-repellent protective film as claimed in claim 1 at least on the recessed portions before a rinsing treatment step of rinsing the wafer surface with a rinsing liquid consisting only of a protic polar solvent or a rinsing liquid containing a protic polar solvent as the principal component, wherein the water-repellent protective film is formed of at least one kind of compounds that serve as the water-repellent protective film forming agent and represented by the general formulas [1] to [3].

8. A method of cleaning a wafer having at its surface an uneven pattern and containing at least one kind of element selected from the group consisting of titanium, tungsten, aluminum, copper, tin, tantalum and ruthenium at surfaces of recessed portions of the uneven pattern, by comprising at least the steps of:
a water-repellent protective film forming step for retaining a liquid chemical for forming a water-repellent protective film at least in the recessed portions of the uneven pattern;
a rinsing treatment step of retaining a rinsing liquid consisting only of a protic polar solvent or a rinsing liquid containing a protic polar solvent as the principal component, on the wafer surface that had undergone the water-repellent protective film forming step;
a rinsing liquid removal step for removing the rinsing liquid; and
a water-repellent protective film removal step for removing a water-repellent protective film;
wherein the liquid chemical for forming a water-repellent protective film is a liquid chemical comprising a water-repellent protective film forming agent for forming a water-repellent protective film at least on the surfaces of the recessed portions, and the water-repellent protective film forming agent is at least one kind of compound represented by the general formulas [1] to [3].

9. A method of cleaning a wafer, as claimed in claim 8, wherein the protic polar solvent is an alcohol.

10. A method of cleaning a wafer, as claimed in claim 8, wherein the water-repellent protective film removal step is performed by at least one treatment selected from the group consisting of: irradiating the wafer surface with light; heating the wafer; exposing the wafer to ozone; irradiating the wafer surface with plasma; and subjecting the wafer surface to corona discharge, thereby removing the water-repellent protective film.
